(19) United States
(12) Patent Application Publication
(10) Pub. No.: US 2025/0192044 A1
(43) Pub. Date: Jun. 12, 2025

(54) SEMICONDUCTOR DEVICE AND METHOD FOR FABRICATING THE SAME

(71) Applicant: NANYA TECHNOLOGY CORPORATION, NEW TAIPEI CITY (TW)

(72) Inventor: YING-CHENG CHUANG, TAOYUAN CITY (TW)

(21) Appl. No.: 19/051,437

(22) Filed: Feb. 12, 2025

Related U.S. Application Data
(63) Continuation of application No. 18/981,766, filed on Dec. 16, 2024.
Application No. 18/981,766 is a continuation-in-part of application No. 18/531,977, filed on Dec. 7, 2023.

(51) Int. Cl. H01L 23/528; H01L 21/768; H01L 23/532

(52) U.S. Cl. CPC H01L 23/5283; H01L 21/76831; H01L 21/76877; H01L 21/76885; H01L 23/53266

(57) ABSTRACT

The present application discloses a semiconductor device and a method for fabricating the semiconductor device. The semiconductor device includes a substrate; and a first word line structure including a first word line dielectric layer positioned in the substrate and including a U-shaped cross-sectional profile, a first bottom conductive layer positioned on the first word line dielectric layer and laterally surrounded by the first word line dielectric layer, a first top conductive layer positioned on the first bottom conductive layer and laterally surrounded by the first word line dielectric layer, and a first capping layer including a bottom portion penetrating through the first top conductive layer and extending to the first bottom conductive layer, and a top portion positioned on the bottom portion and laterally surrounded by the first word line dielectric layer.

### CROSS-REFERENCE TO RELATED APPLICATION

This application is a continuation application of U.S. Non-Provisional application Ser. No. 18/981,766 filed Dec. 16, 2024, which is a continuation-in-part application of U.S. Non-Provisional application Ser. No. 18/531,977 filed Dec. 7, 2023. The entirety of the above-mentioned patent application is hereby incorporated by reference herein and made a part of this specification.

### TECHNICAL FIELD

The present disclosure relates to a semiconductor device and a method for fabricating the semiconductor device, and more particularly, to a semiconductor device with bottom and top conductive layers.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate with a source region and a drain region; a first word line structure disposed between the source region and the drain region; a first dielectric layer positioned over the substrate; and a conductive contact penetrating through the first dielectric layer and extending into the drain region of the substrate. The first word line structure includes a first word line dielectric layer positioned in the substrate and including a U-shaped cross-sectional profile, a first bottom conductive layer positioned on the first word line dielectric layer and laterally surrounded by the first word line dielectric layer, a first top conductive layer positioned on the first bottom conductive layer and laterally surrounded by the first word line dielectric layer, and a first capping layer including a bottom portion penetrating through the first top conductive layer and extending to the first bottom conductive layer, and a top portion positioned on the bottom portion and laterally surrounded by the first word line dielectric layer. The conductive contact comprises a conductive layer and a barrier layer covering a sidewall and a bottom surface of the conductive layer. A first thickness of the barrier layer on the sidewall of the conductive layer is less than a second thickness of the barrier layer under the bottom surface of the conductive layer.

Another aspect of the present disclosure provides a semiconductor device including a substrate with a source region and a plurality of drain regions; a plurality of isolation layers disposed in the substrate; a first word line structure disposed in the substrate and between the isolation layers; a second word line structure disposed in the isolation layers; a first dielectric layer disposed over the substrate; a second dielectric layer disposed over the first dielectric layer; a first conductive contact and a second conductive contact respectively penetrating through the first dielectric layer and extending into one of the drain regions; a first conductive pillar and a second conductive pillar disposed on the first conductive contact and the second conductive contact, respectively; and a first landing pad and a second landing pad disposed on the first conductive pillar and the second conductive pillar, respectively. The first and second landing pads and the first and second conductive pillars are respectively made of different conductive materials, and a resistivity of the first and second landing pads is less than a resistivity of the first and second conductive pillars.

Another aspect of the present disclosure provides a method for fabricating a semiconductor device including providing a substrate and forming a first trench in the substrate, and conformally forming a layer of first dielectric material in the first trench; forming a first bottom conductive layer on the layer of first dielectric material within the first trench, and forming a first top conductive layer on the first bottom conductive layer within the first trench; conformally forming a layer of spacer material on the first top conductive layer and the layer of first dielectric material; performing a punch-through process to turn the layer of spacer material into a plurality of first spacers attached to the layer of first dielectric material, resulting in a first inner trench, which separates the plurality of first spacers and partially exposes the first top conductive layer; deepening the first inner trench to form a first extended inner trench that penetrates the first top conductive layer and extends to the first bottom conductive layer; removing the plurality of first spacers and forming a layer of capping material to completely fill the first trench; performing a planarization process to turn the layer of first dielectric material into a first word line dielectric layer and turn the layer of capping material into a first capping layer; depositing a first dielectric layer on the substrate; perform an etching process to form an opening penetrating through the first dielectric layer and extending into the substrate; performing an anisotropic deposition process to form a barrier layer covering a sidewall and a bottom surface of the opening; and forming a conductive layer disposed over and surrounded by the barrier layer. The first word line dielectric layer, the first bottom conductive layer, the first top conductive layer, and the first capping layer together comprise a first word line structure. A first thickness of the barrier layer on the sidewall of the opening is less than a second thickness of the barrier layer on the bottom surface of the opening.

Another aspect of the present disclosure provides a method for fabricating a semiconductor device including providing a semiconductor structure, wherein the semiconductor structure comprises a substrate with a source region and a plurality of drain regions, a plurality of first word line structures disposed in the substrate, a first dielectric layer disposed over the substrate and the first word line structures, and a plurality of conductive contacts penetrating through the first dielectric layer and extending into the drain regions; forming a first conductive layer on the first dielectric layer and the conductive contacts, and forming a second conductive layer on the first conductive layer; performing a first etching process on the second conductive layer to form a first landing pad over one of the conductive contacts, and a second landing pad over another one of the conductive contacts; and performing a second etching process on the first conductive layer to form a first conductive pillar below the first landing pad and a second conductive pillar below the second landing pad. The first word line structure comprises a first word line dielectric layer positioned in the substrate and comprising a U-shaped cross-sectional profile; a first bottom conductive layer positioned on the first word line dielectric layer and laterally surrounded by the first word line dielectric layer; a first top conductive layer positioned on the first bottom conductive layer and laterally surrounded by the first word line dielectric layer; a first capping layer comprising a bottom portion penetrating through the first top conductive layer and extending to the first bottom conductive layer; and a top portion positioned on the bottom portion and laterally surrounded by the first word line dielectric layer. The first and second landing pads and the first and second conductive pillars are respectively made of different conductive materials, and a resistivity of the first and second landing pads is less than a resistivity of the first and second conductive pillars.

Due to a design of a semiconductor device of the present disclosure, issues such as line end wiggling may be mitigated by substituting sections of a first top conductive layer with a bottom portion of a first capping layer. Furthermore, a gate-induced drain leakage is minimized by using a first bottom conductive layer and the first top conductive layer composed of materials with differing work functions.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

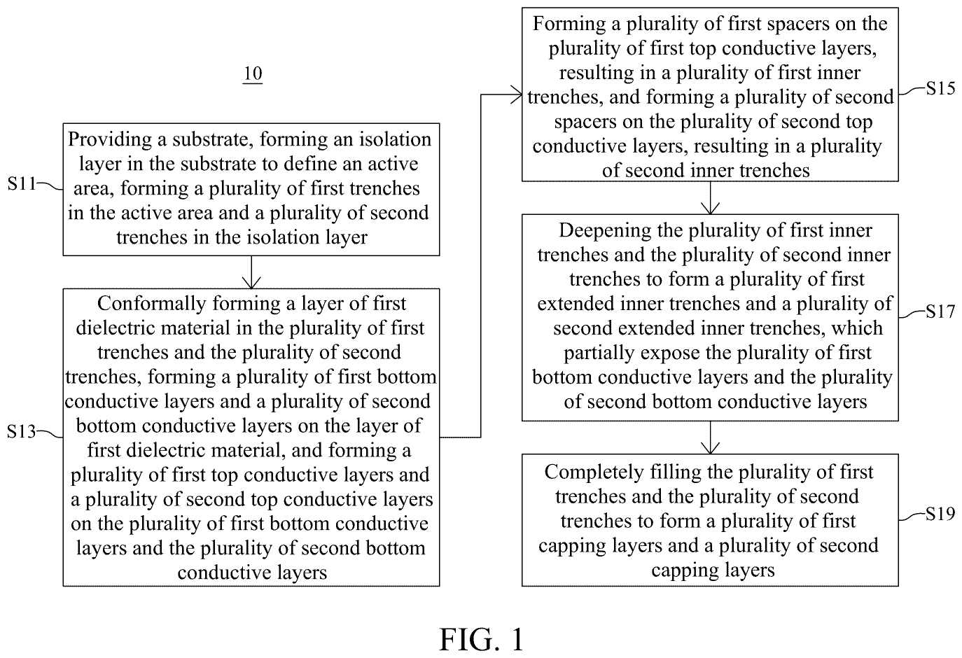

FIG. 1 illustrates, in flowchart diagram form, a method for fabricating a semiconductor device in accordance with one embodiment of the present disclosure.

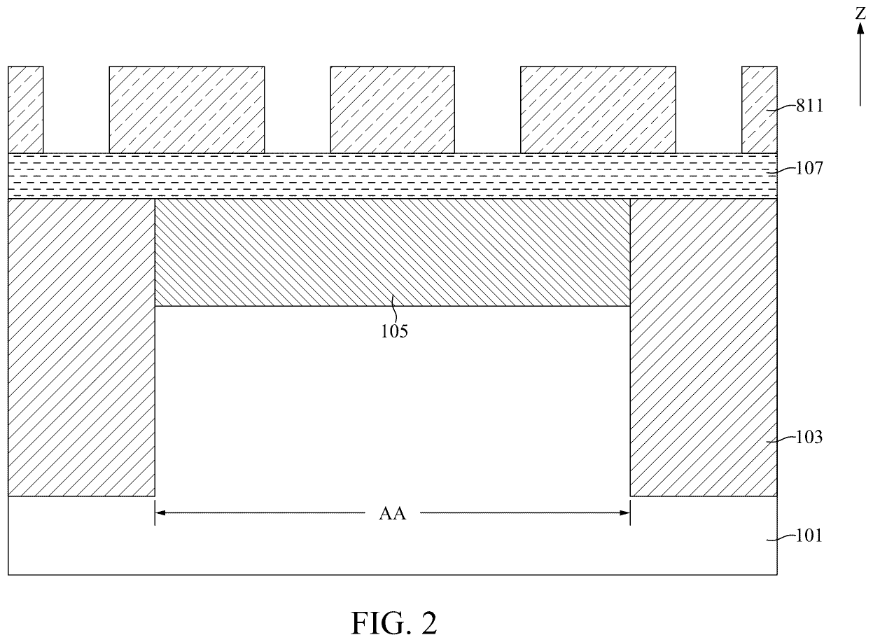

FIGS. 2 to 16 illustrate, in schematic cross-sectional view diagrams, a process for fabricating the semiconductor device in accordance with one embodiment of the present disclosure.

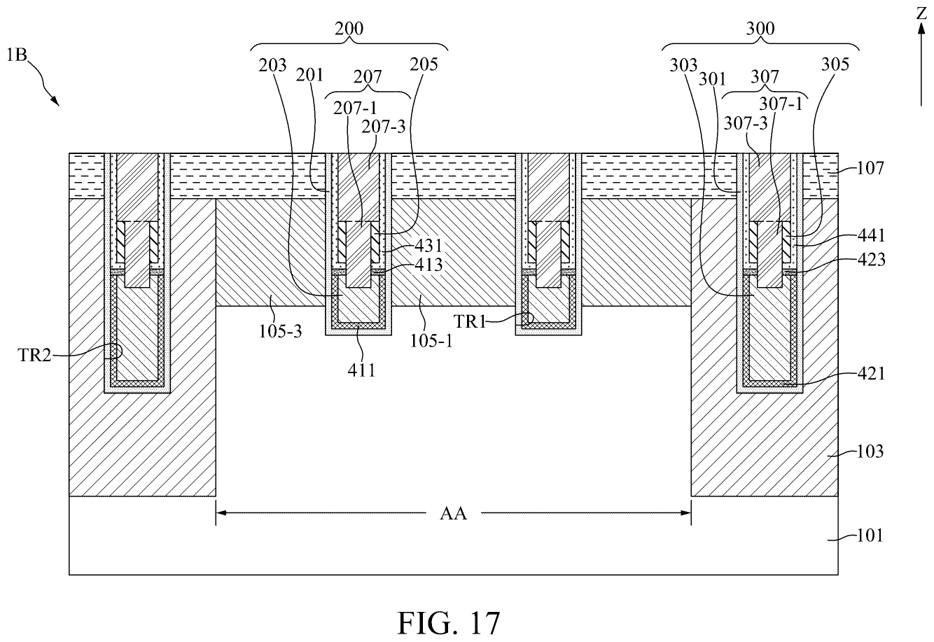

FIG. 17 illustrates, in a schematic cross-sectional view diagram, a semiconductor device in accordance with another embodiment of the present disclosure.

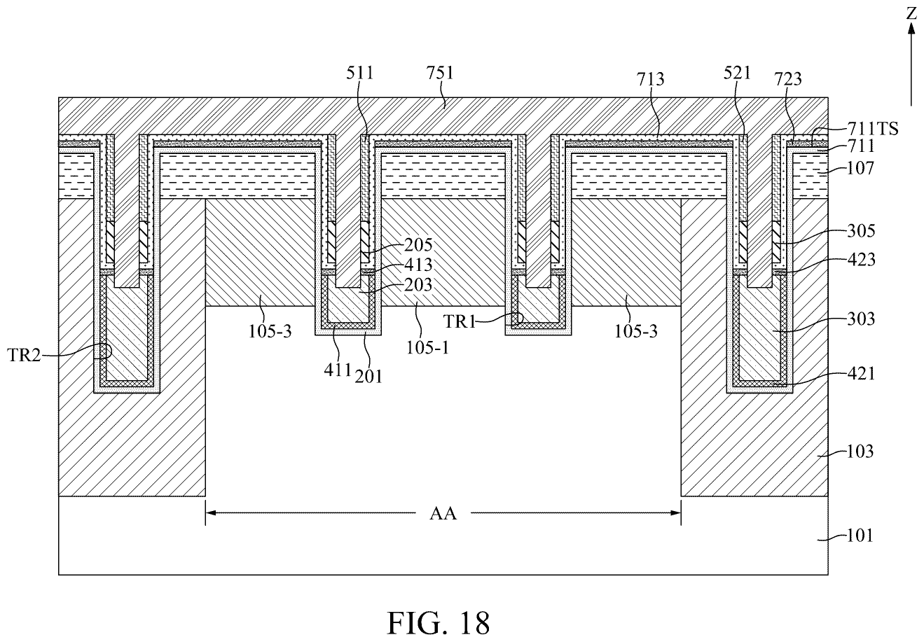

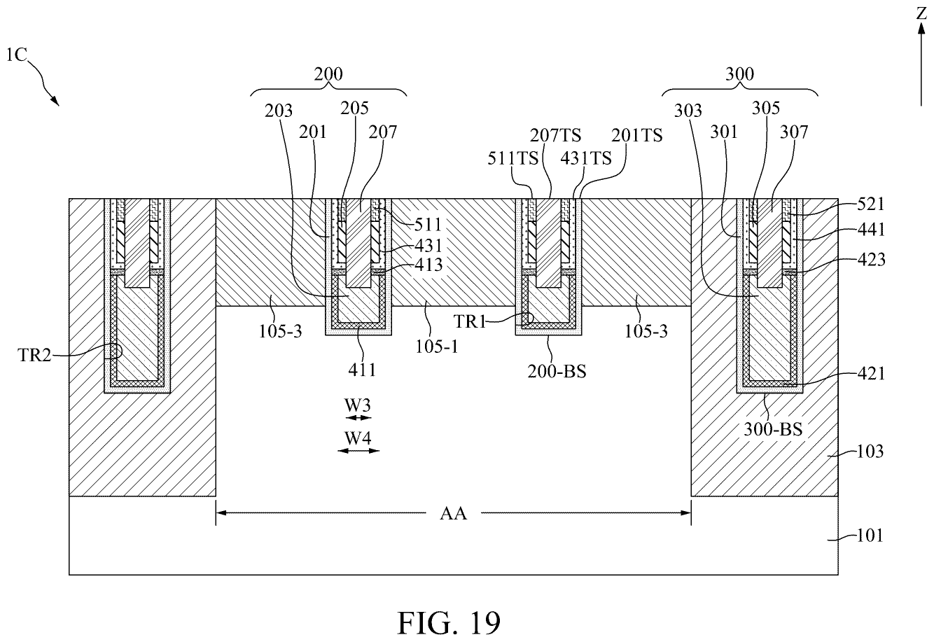

FIGS. 18 and 19 illustrate, in schematic cross-sectional view diagrams, part of a process for fabricating a semiconductor device in accordance with another embodiment of the present disclosure.

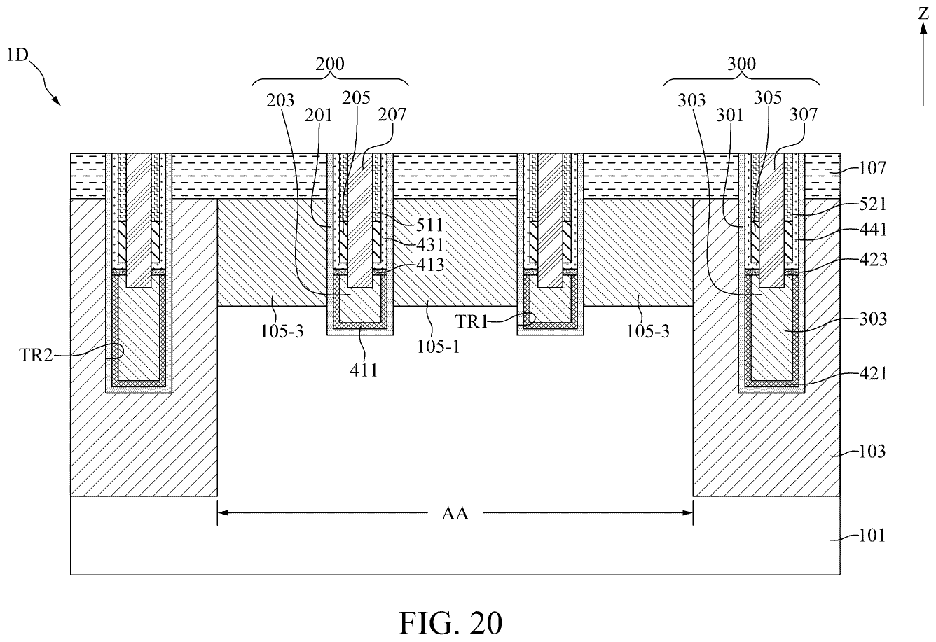

FIG. 20 illustrates, in a schematic cross-sectional view diagram, a semiconductor device in accordance with another embodiment of the present disclosure.

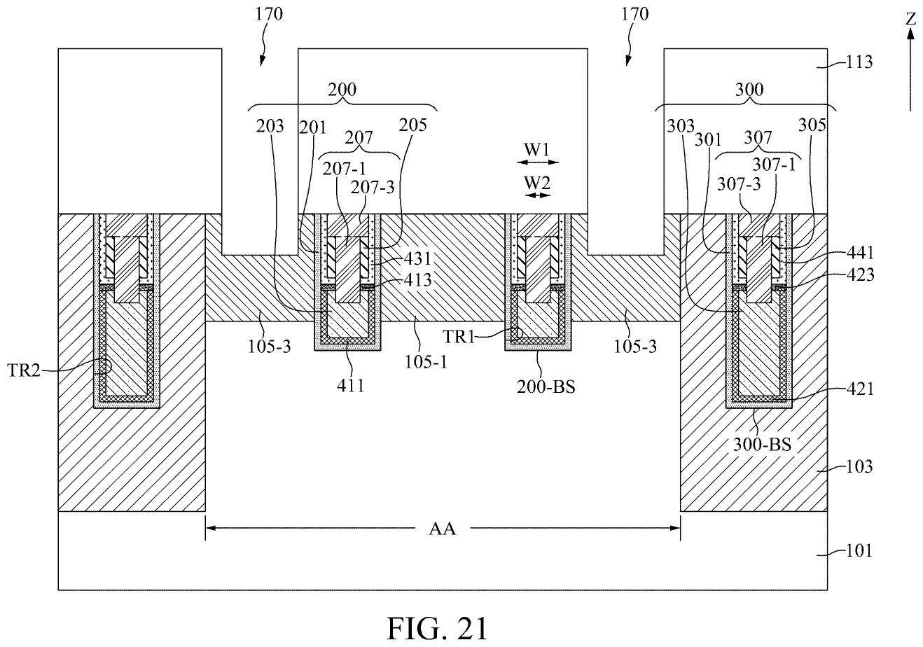

FIGS. 21 to 23 illustrate, in schematic cross-sectional view diagrams, part of a process for fabricating a semiconductor device in accordance with another embodiment of the present disclosure.

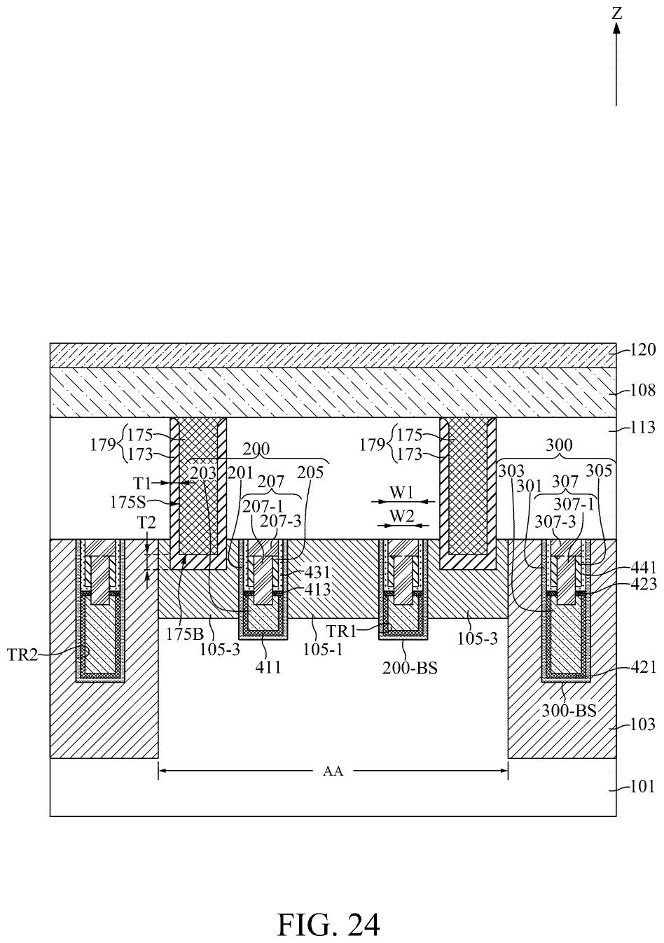

FIGS. 24 to 32 illustrate, in schematic cross-sectional view diagrams, part of a process for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to the other element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

FIG. 1 illustrates, in flowchart diagram form, a method 10 for fabricating a semiconductor device 1A in accordance with one embodiment of the present disclosure. FIGS. 2 to 16 illustrate, in schematic cross-sectional view diagrams, a process for fabricating the semiconductor device 1A in accordance with one embodiment of the present disclosure.

With reference to FIGS. 1 to 3, in step S11, a substrate 101 is provided, an isolation layer 103 is formed in the substrate 101 to define an active area AA, a plurality of first trenches TR1 are formed in the active area AA, and a plurality of second trenches TR2 are formed in the isolation layer 103.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or another III-V compound semiconductor or II-VI compound semiconductor; or a combination thereof.

With reference to FIG. 2, an isolation layer 103 may be formed in the substrate 101. A series of deposition processes may be performed to deposit a pad oxide layer and a pad nitride layer on the substrate 101. A photolithography process and a subsequent etching process, such as anisotropic dry etching, may be conducted to form trenches that penetrate through the pad oxide layer and the pad nitride layer, and extend to the substrate 101. An insulating material, such as silicon oxide or another applicable insulating material, may then be deposited into the trenches. A planarization process, such as chemical mechanical polishing, may subsequently be performed to expose a top surface of the substrate 101, removing excess insulating material and providing a substantially flat surface for subsequent processing steps, while concurrently forming the isolation layer 103. In some embodiments, the isolation layer 103 may define an active area (AA) in the substrate 101.

With reference to FIG. 2, an impurity region 105 may be formed in the active area (AA). In some embodiments, the impurity region 105 may be created through an implantation process using either p-type or n-type dopants. The term “p-type dopant” refers to an impurity that, when added to an intrinsic semiconductor material, creates deficiencies of valence electrons. In silicon-containing semiconductor materials, examples of p-type dopants include, but are not limited to, boron, aluminum, gallium, and indium. Conversely, the term “n-type dopant” refers to an impurity that contributes free electrons to the intrinsic semiconductor material. In silicon-containing materials, examples of n-type dopants include, but are not limited to, antimony, arsenic, and phosphorus.

With reference to FIG. 2, a bottom dielectric layer 107 may be formed on the substrate 101 to completely cover the impurity region 105 and the isolation layer 103. The bottom dielectric layer 107 may be made of a material that exhibits etching selectivity relative to the substrate 101 and the isolation layer 103. Examples of materials of the bottom dielectric layer 107 include silicon nitride, boron nitride, silicon boron nitride, phosphorus boron nitride, boron carbon silicon nitride, and combinations thereof. In some embodiments, the bottom dielectric layer 107 may specifically be silicon nitride. In some embodiments, the bottom dielectric layer 107 may be formed using a process such as chemical vapor deposition, plasma-enhanced chemical vapor deposition, or another applicable deposition process.

With reference to FIG. 2, a first mask layer 811 may be formed on the bottom dielectric layer 107. In some embodiments, the first mask layer 811 may consist of a photoresist layer that includes a pattern of the plurality of first trenches TR1 and the plurality of second trenches TR2.

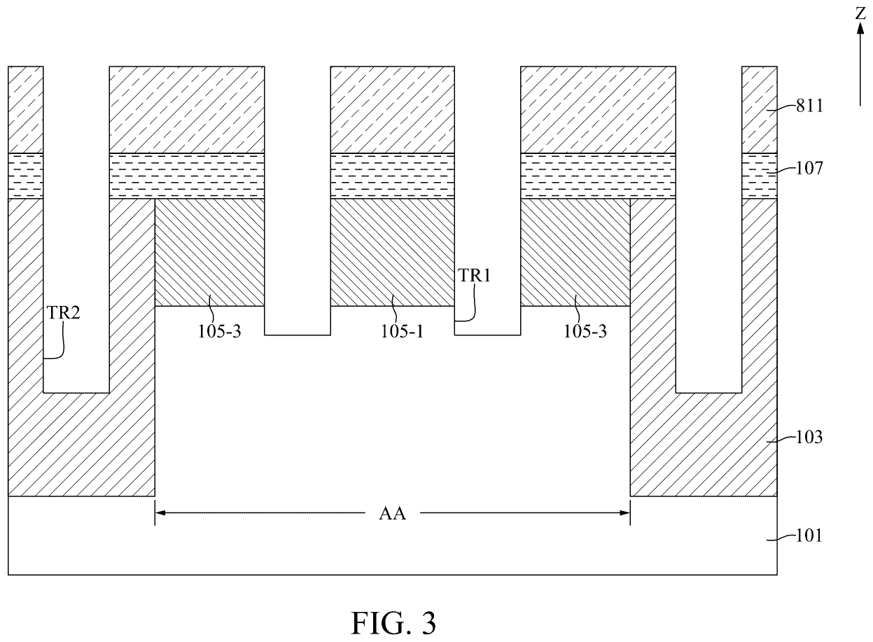

With reference to FIG. 3, a trench etching process may be performed using the first mask layer 811 as a mask to remove portions of the bottom dielectric layer 107, the isolation layer 103, and the substrate 101, thereby concurrently forming the plurality of first trenches TR1 in the substrate 101 and the plurality of second trenches TR2 in the isolation layer 103. In some embodiments, the plurality of first trenches TR1 may be shallower than the plurality of second trenches TR2.

After the formation of the trenches TR1, TR2, the first mask layer 811 may be removed. The impurity region 105 may then be divided into a source region 105-1 and two drain regions 105-3. The drain regions 105-3 may be located between the isolation layer 103 and the plurality of first trenches TR1, and the source region 105-1 may be positioned between the plurality of first trenches TR1. Additionally, the bottom dielectric layer 107 may be divided into multiple segments when viewed from a cross-sectional perspective.

With reference to FIG. 1 and FIGS. 4 to 10, in step S13, a layer of first dielectric material 711 may be conformally formed in the plurality of first trenches TR1 and the plurality of second trenches TR2; a plurality of first bottom conductive layers 203 and a plurality of second bottom conductive layers 303 may be formed on the layer of first dielectric material 711; and a plurality of first top conductive layers 205 and a plurality of second top conductive layers 305 may be formed on the plurality of first bottom conductive layers 203 and the plurality of second bottom conductive layers 303.

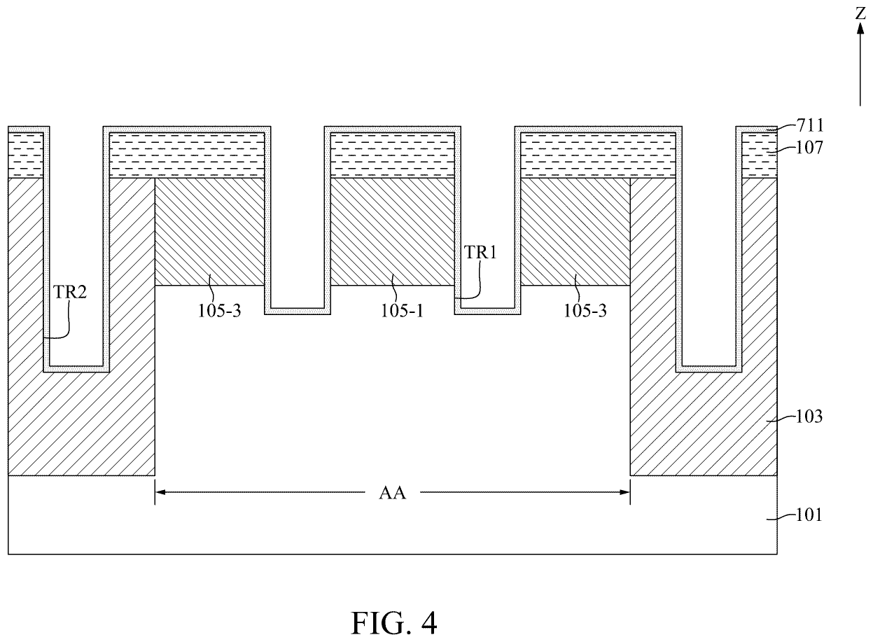

With reference to FIG. 4, the layer of first dielectric material 711 may be conformally formed on the bottom dielectric layer 107 and in the plurality of first trenches TR1 and the plurality of second trenches TR2. The layer of first dielectric material 711 may have a U-shaped cross-sectional profile within the trenches TR1, TR2. In other words, the layer of first dielectric material 711 may be conformally formed along surfaces of the trenches TR1, TR2. In some embodiments, the layer of first dielectric material 711 may have a thickness in a range of about 1 nm to about 7 nm, including about 1 nm, about 2 nm, about 3 nm, about 4 nm, about 5 nm, about 6 nm, or about 7 nm.

In some embodiments, the layer of first dielectric material 711 may be formed using a deposition process, such as a chemical vapor deposition or an atomic layer deposition. In some embodiments, after a liner polysilicon layer is deposited, the layer of first dielectric material 711 may be formed by applying a radical oxidizing process to the liner polysilicon layer. In some embodiments, after a liner silicon nitride layer is formed, the layer of first dielectric material 711 may be formed by applying a radical oxidizing process to the liner silicon nitride layer. In some embodiments, the first dielectric material 711 may include a material having etching selectivity to the bottom dielectric layer 107 and the substrate 101. In some embodiments, the first dielectric material 711 may include a high-k material, an oxide (such as silicon oxide), a nitride, an oxynitride, or a combination thereof.

In some embodiments, the high-k dielectric material may include a hafnium-containing material. The hafnium-containing material may be, for example, hafnium oxide, hafnium silicon oxide, hafnium silicon oxynitride, or a combination thereof. In some embodiments, the high-k dielectric material may be, for example, lanthanum oxide, lanthanum aluminum oxide, zirconium oxide, zirconium silicon oxide, zirconium silicon oxynitride, aluminum oxide or a combination thereof.

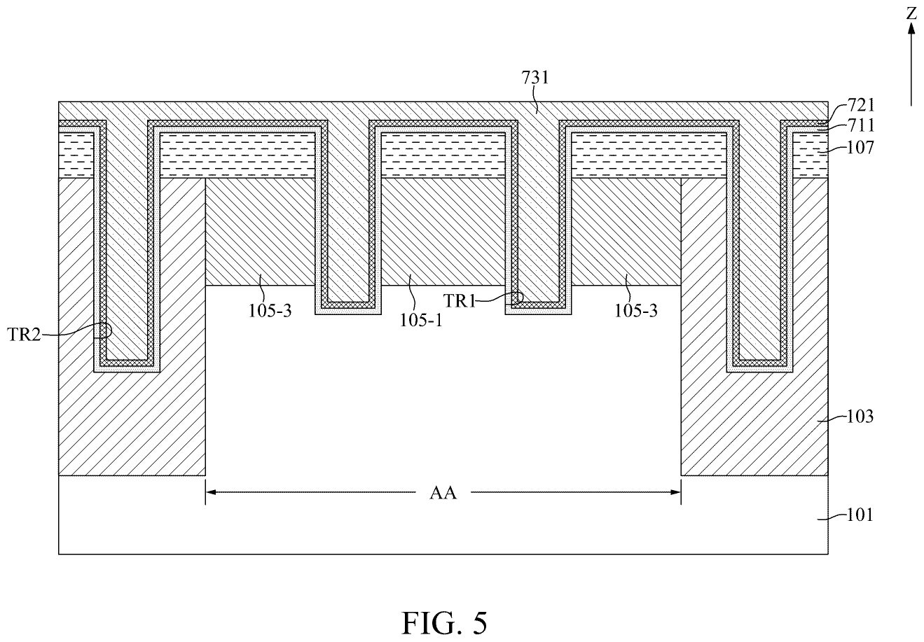

With reference to FIG. 5, a layer of first barrier material 721 may be conformally formed on the layer of first dielectric material 711. In some embodiments, the first barrier material 721 may be, for example, titanium nitride, titanium, or a combination thereof. In some embodiments, the first barrier material 721 may be, for example, titanium nitride. In some embodiments, the layer of first barrier material 721 may be formed using an atomic layer deposition, a physical vapor deposition, a chemical vapor deposition, or another applicable deposition process.

With reference to FIG. 5, a layer of first conductive material 731 may be formed on the layer of first barrier material 721 and may completely fill the trenches TR1, TR2. In some embodiments, the first conductive material 731 may be, for example, tungsten, cobalt, zirconium, tantalum, aluminum, ruthenium, copper, metal carbides (e.g., tantalum carbide, titanium carbide, or tantalum magnesium carbide), transition metal aluminides, titanium nitride, or a combination thereof. In some embodiments, the first conductive material 731 may be, for example, tungsten or titanium nitride. In some embodiments, the layer of first conductive material 731 may be formed using a physical vapor deposition, a sputtering, an electroplating, an electroless plating, a chemical vapor deposition, or another applicable deposition process. In some embodiments, the layer of first barrier material 721 may be optional. In other words, the layer of first conductive material 731 may be formed on the layer of first dielectric material 711 and may completely fill the trenches TR1, TR2.

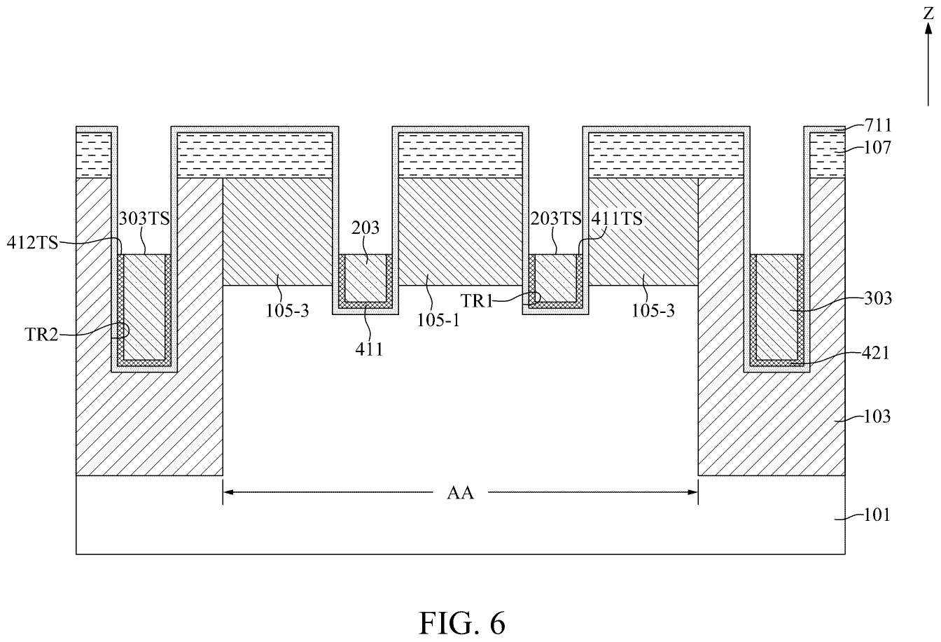

With reference to FIG. 6, an etch-back process may be performed to remove portions of the first barrier material 721 and the first conductive material 731. After the etch-back process is performed, remaining portions of the first barrier material 721 are turned into a plurality of first bottom barrier layers 411 and a plurality of second bottom barrier layers 421. The plurality of first bottom barrier layers 411 may be formed on the layer of first dielectric material 711 and within the plurality of first trenches TR1. The plurality of second bottom barrier layers 421 may be formed on the layer of first dielectric material 711 and within the plurality of second trenches TR2.

Remaining portions of the first conductive material 731 are turned into the plurality of first bottom conductive layers 203 and the plurality of second bottom conductive layers 303. The plurality of first bottom conductive layers 203 may be formed on the plurality of first bottom barrier layers 411 and within the plurality of first trenches TR1. The plurality of second bottom conductive layers 303 may be formed on the plurality of second bottom barrier layers 421 and within the plurality of second trenches TR2.

For brevity, clarity, and convenience of description, only one first bottom barrier layer 411, one second bottom barrier layer 421, one first bottom conductive layer 203, and one second bottom conductive layer 303 are described.

With reference to FIG. 6, in some embodiments, a top surface 203TS of the first bottom conductive layer 203, a top surface 303TS of the second bottom conductive layer 303, a top surface 411TS of the first bottom barrier layer 411, and a top surface 421TS of the second bottom barrier layer 421 may be substantially coplanar. In some embodiments, the top surface 203TS of the first bottom conductive layer 203, the top surface 303TS of the second bottom conductive layer 303, the top surface 411TS of the first bottom barrier layer 411, and the top surface 421TS of the second bottom barrier layer 421 may be at different vertical levels.

In some embodiments, portions of the layer of first dielectric material 711 formed on the bottom dielectric layer 107 may be reduced in thickness due to consumption during etch-back and/or post-etching cleaning processes. Consequently, the portions of the layer of first dielectric material 711 on the bottom dielectric layer 107 may be thinner than other portions of the layer of first dielectric material 711.

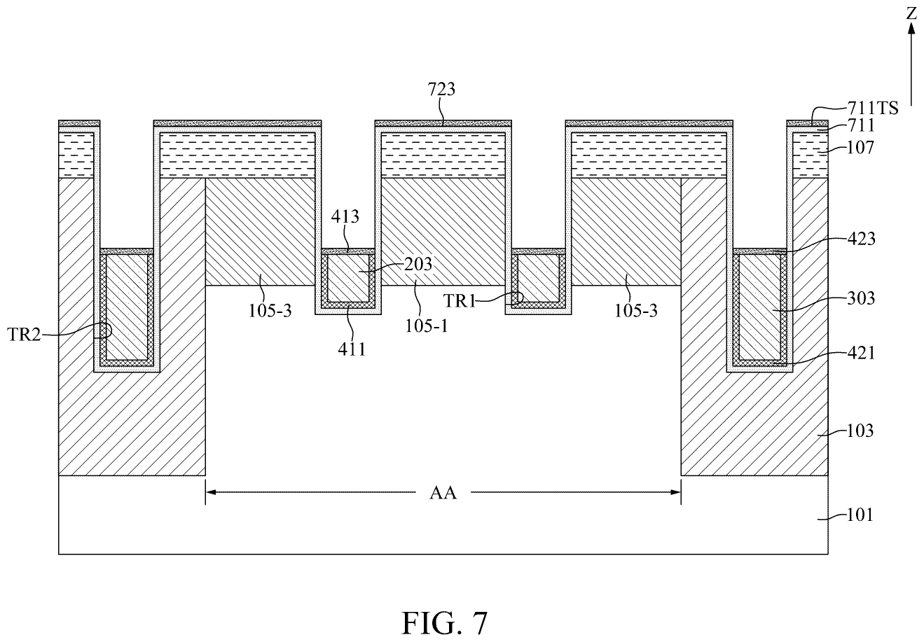

With reference to FIG. 7, a layer of second barrier material 723 may be formed on the top surface 711TS of the layer of first dielectric material 711 and formed within the trenches TR1, TR2. The second barrier material 723 formed within the first trenches TR1 may be referred to as a plurality of first middle barrier layers 413 and may be formed on the plurality of first bottom conductive layers 203. The second barrier material 723 formed within the second trenches TR2 may be referred to as a plurality of second middle barrier layers 423 and may be formed on the plurality of second bottom conductive layers 303. For brevity, clarity, and convenience of description, only one first middle barrier layer 413 and one second middle barrier layer 423 are described.

In some embodiments, the first middle barrier layer 413 may cover the first bottom barrier layer 411. The second middle barrier layer 423 may cover the second bottom barrier layer 421. In other words, the first bottom conductive layer 203 may be surrounded by the first bottom barrier layer 411 and the first middle barrier layer 413 in a cross-sectional perspective. The second bottom conductive layer 303 may be surrounded by the second bottom barrier layer 421 and the second middle barrier layer 423 in a cross-sectional perspective.

In some embodiments, the second barrier material 723 (i.e., the first middle barrier layer 413 and the second middle barrier layer 423) may be, for example, titanium nitride, titanium, or a combination thereof. In some embodiments, the second barrier material 723 may be, for example, titanium nitride. In some embodiments, the second barrier material 723 may be a material same as a material of the first bottom barrier layer 411. In some embodiments, the layer of second barrier material 723 may be formed using a radio-frequency physical vapor deposition or another applicable deposition process. In some embodiments, the layer of second barrier material 723 may be optional. In other words, the subsequent layer may be directly formed on the first bottom conductive layer 203 or the second bottom conductive layer 303.

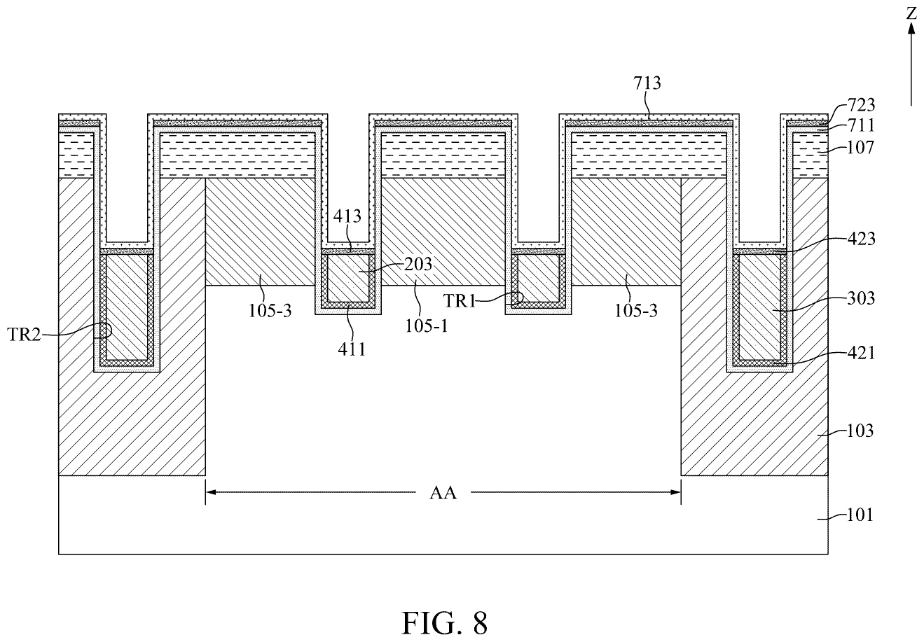

With reference to FIG. 8, a layer of first insulating material 713 may be conformally formed on the layer of first dielectric material 711, the bottom dielectric layer 107, the layer of second barrier material 723, the plurality of first middle barrier layers 413, and the plurality of second middle barrier layers 423. In some embodiments, due to the conforming of the layer of first insulating material 713 to the layer of first dielectric material 711, the first middle barrier layer 413, and the second middle barrier layer 423, the layer of first insulating material 713 formed within the trenches TR1, TR2 may exhibit a U-shaped cross-sectional profile. In some embodiments, the first insulating material 713 may be, for example, a material having etching selectivity to the bottom dielectric layer 107. In some embodiments, the first dielectric material 711 and the first insulating material 713 may include a same material. In some embodiments, the first insulating material 713 may be, for example, silicon oxide. In some embodiments, the layer of first insulating material 713 may be formed using an atomic layer deposition, a chemical vapor deposition, or another applicable deposition process. In some embodiments, the layer of first insulating material 713 may be optional. In other words, the subsequent layer may be directly formed on the first bottom conductive layer 203 or the second bottom conductive layer 303.

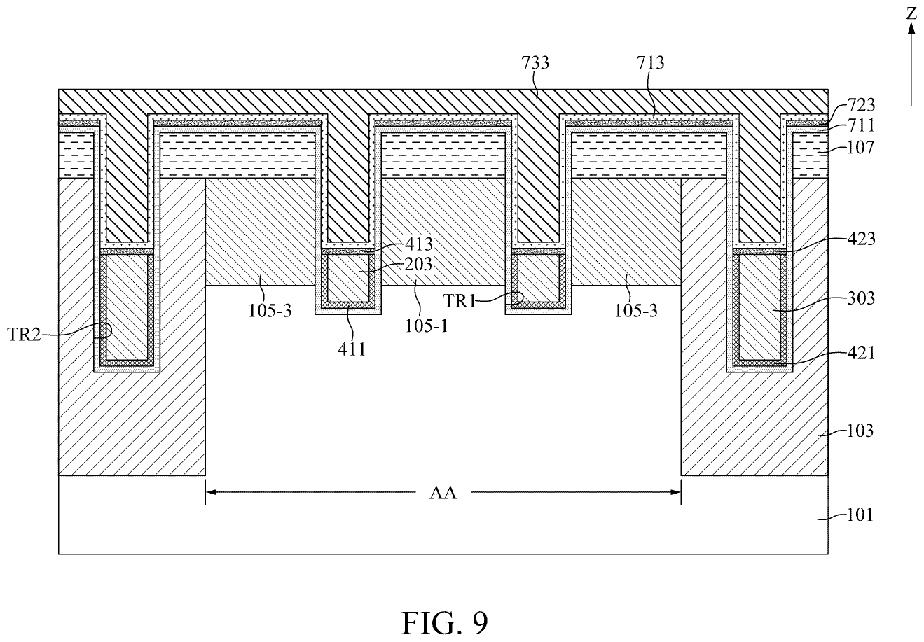

With reference to FIG. 9, a layer of second conductive material 733 may be formed on the layer of first insulating material 713 and may completely fill the trenches TR1, TR2. In some embodiments, the second conductive material 733 may be, for example, polycrystalline silicon, polycrystalline germanium, polycrystalline silicon germanium, doped polycrystalline silicon, doped polycrystalline germanium, doped polycrystalline silicon germanium, or a combination thereof. In some embodiments, the layer of second conductive material 733 may be doped with p-type dopants or n-type dopants. In some embodiments, the layer of second conductive material 733 may be formed using a chemical vapor deposition or another applicable deposition process. In some embodiments, the doping may be achieved through an implantation process after the deposition process is performed. In some embodiments, the doping may be performed by incorporating dopants during the deposition process.

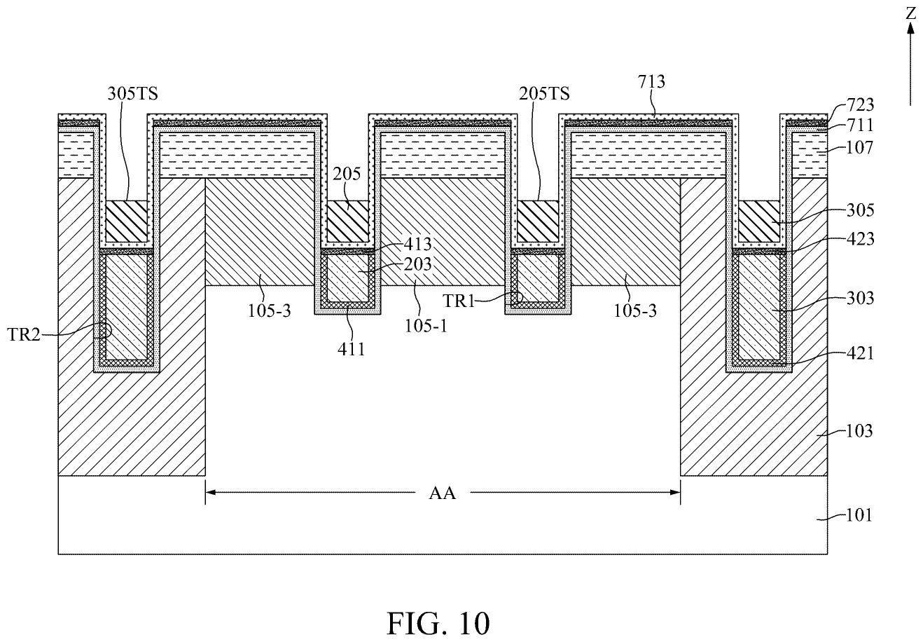

With reference to FIG. 10, an etch-back process may be subsequently performed to remove portions of the second conductive material 733 to form the plurality of first top conductive layers 205 and the plurality of second top conductive layers 305. For brevity, clarity, and convenience of description, only one first top conductive layer 205 and one second top conductive layer 305 are described. The first top conductive layer 205 may be formed on the layer of first insulating material 713 within the first trench TR1. The second top conductive layer 305 may be formed on the layer of first insulating material 713 within the second trench TR2. In some embodiments, a top surface 205TS of the first top conductive layer 205 and a top surface 305TS of the second top conductive layer 305 may be substantially coplanar.

With reference to FIGS. 1, 11 and 12, in step S15, a plurality of first spacers 511 may be formed on the first top conductive layers 205, resulting in the formation of first inner trenches 531. Similarly, a plurality of second spacers 521 may be formed on the second top conductive layers 305, resulting in the formation of second inner trenches 541.

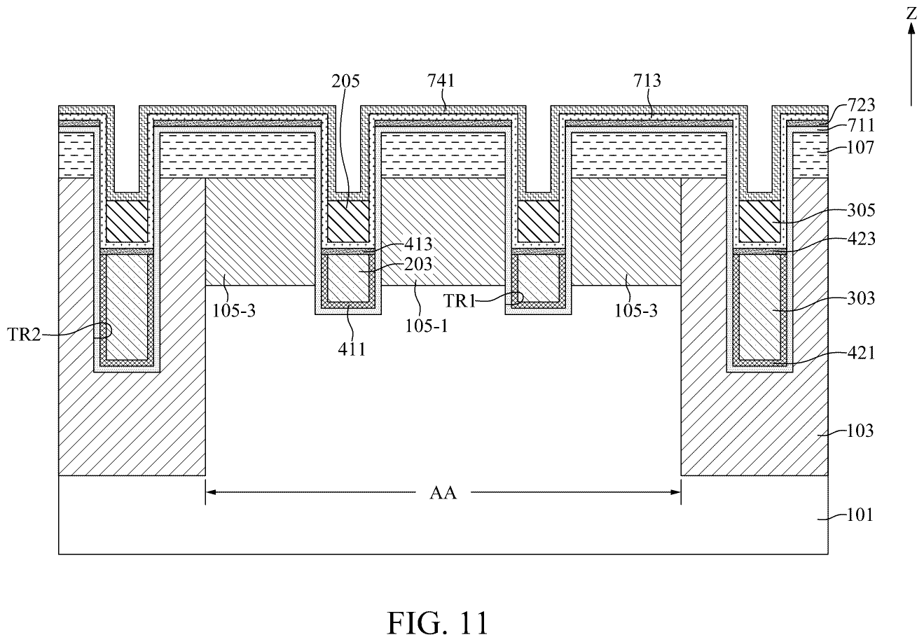

With reference to FIG. 11, a layer of spacer material 741 may be conformally formed on the layer of first insulating material 713, the plurality of first top conductive layers 205, and the plurality of second top conductive layers 305. The trenches TR1, TR2 are not completely filled by the layer of spacer material 741. In some embodiments, the spacer material 741 may be a material having etching selectivity to the first top conductive layer 205 and the second top conductive layer 305. In some embodiments, the spacer material 741 may be a material having etching selectivity to the first top conductive layer 205, the first insulating material 713, and/or the first dielectric material 711. In some embodiments, the spacer material 741 may be, for example, silicon nitride. In some embodiments, the layer of spacer material 741 may be formed using an atomic layer deposition, a chemical vapor deposition, or another applicable deposition process.

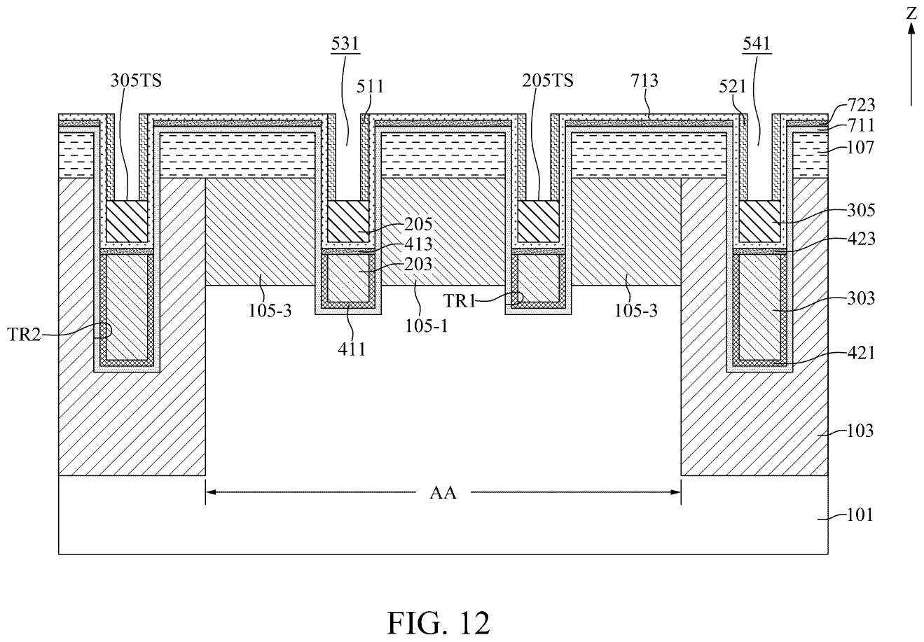

With reference to FIG. 12, a punch-through process may be performed to remove a portion of the spacer material 741. In some embodiments, the punch-through process may be an anisotropic etching process such as an anisotropic dry etching process. After the punch-through process is performed, the remaining spacer material 741 in the first trench TR1 may be referred to as the plurality of first spacers 511. The first inner trench 531 may be formed between an adjacent pair of the plurality of first spacers 511. The top surface 205TS of the first top conductive layer 205 may be partially exposed through the first inner trench 531. The remaining spacer material 741 in the second trench TR2 may be referred to as the plurality of second spacers 521. The second inner trench 541 may be formed between an adjacent pair of the plurality of second spacers 521. The top surface 305TS of the second top conductive layer 305 may be partially exposed through the second inner trench 541.

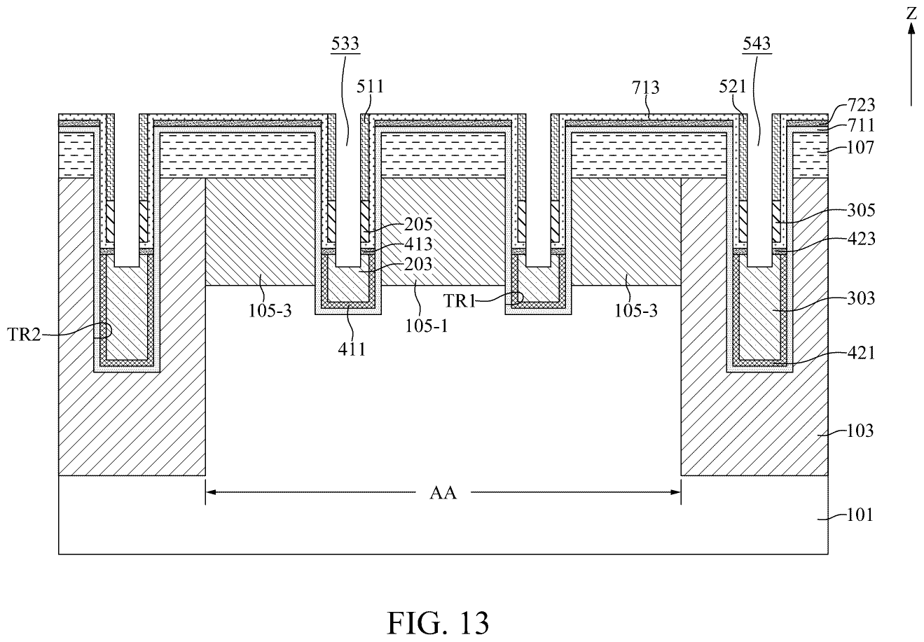

With reference to FIGS. 1 and 13, in step S17, the plurality of first inner trenches 531 and the plurality of second inner trenches 541 may be deepened to form a plurality of first extended inner trenches 533 and a plurality of second extended inner trenches 543, which partially expose the plurality of first bottom conductive layers 203 and the plurality of second bottom conductive layers 303.

With reference to FIG. 13, the deepening of the first inner trench 531 and the second inner trench 541 may be achieved through an anisotropic etching process, using the plurality of first spacers 511 and the plurality of second spacers 521 as masks. For example, the deepening might be facilitated by an anisotropic dry etching process. In some embodiments, the anisotropic dry etching process may be a multi-stage etching process, with different stages employing varying etching chemistries to selectively remove targeted layer(s).

For brevity, clarity, and convenience of description, only one first extended inner trench 533 and one second extended inner trench 543 are described.

With reference to FIG. 13, the first inner trench 531 is deepened to form the first extended inner trench 533, which penetrates through the first top conductive layer 205, the layer of first insulating material 713, and the first middle barrier layer 413, and extends down to the first bottom conductive layer 203. Similarly, the second extended inner trench 543 penetrates through the second top conductive layer 305, the layer of first insulating material 713, and the second middle barrier layer 423, and reaches the second bottom conductive layer 303. Consequently, both the first top conductive layer 205 and the first middle barrier layer 413 are bifurcated into two segments by the first extended inner trench 533. Similarly, the second top conductive layer 305 and the second middle barrier layer 423 are each split into two segments by the second extended inner trench 543. The layer of first insulating material 713 becomes segmented by both the first and second extended inner trenches 533, 543, while the first bottom conductive layer 203 and the second bottom conductive layer 303 are partially revealed through the first and second extended inner trenches 533, 543.

With reference to FIG. 1 and FIGS. 14 to 16, in step S19, the plurality of first trenches TR1 and the plurality of second trenches TR2 may be completely filled to form a plurality of first capping layers 207 and a plurality of second capping layers 307.

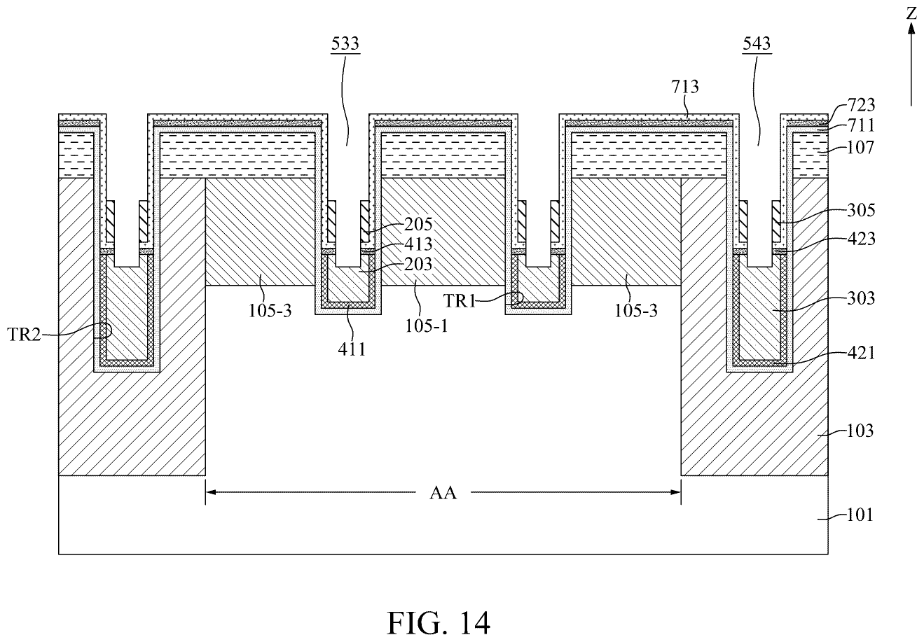

With reference to FIG. 14, the plurality of first spacers 511 and the plurality of second spacers 521 may be selectively removed. Following the removal of the first and second spacers 511, 521, each of the first extended inner trench 533 and the second extended inner trench 543 may exhibit a T-shaped space when viewed in cross-section. In some embodiments, an upper portion of the first extended inner trench 533 is wider than a lower portion of the first extended inner trench 533. In some embodiments, an upper portion of the second extended inner trench 543 is wider than a lower portion of the second extended inner trench 543.

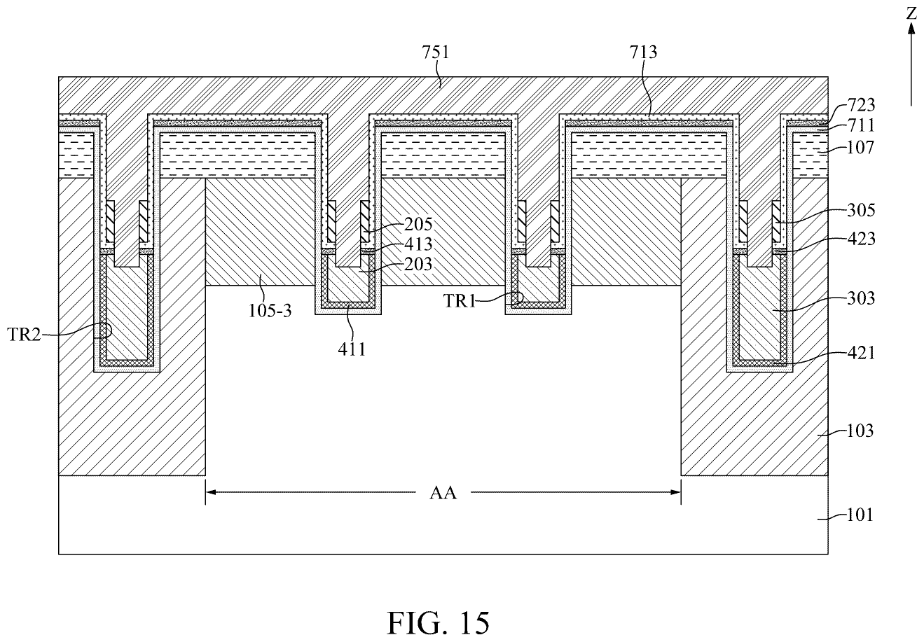

With reference to FIG. 15, a layer of capping material 751 may be formed to completely fill the first extended inner trench 533 and the second extended inner trench 543, and to fill the trenches TR1, TR2. In some embodiments, the capping material 751 may be, for example, a material having etching selectivity to the first insulating material 713 and the first dielectric material 711. In some embodiments, the capping material 751 may be, for example, silicon nitride, boron nitride, silicon boron nitride, phosphorus boron nitride, boron carbon silicon nitride, or a combination thereof. In some embodiments, the capping material 751 may be, for example, silicon nitride. In some embodiments, the layer of capping material 751 may be formed using a chemical vapor deposition, a plasma-enhanced chemical vapor deposition, or another applicable deposition process.

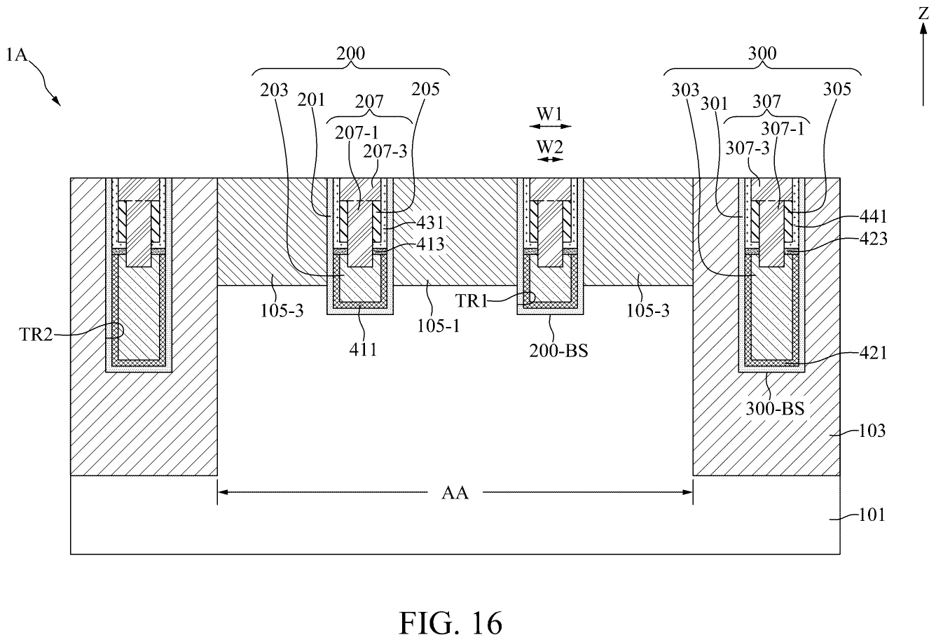

With reference to FIG. 16, a planarization process, such as chemical mechanical polishing, may be performed until the isolation layer 103 (or the substrate 101) is exposed to remove excess material and provide a substantially flat surface for subsequent processing steps. After the planarization process is performed, remaining first dielectric material 711 within the first trench TR1 may be referred to as a first word line dielectric layer 201, while remaining first dielectric material 711 within the second trench TR2 may be referred to as a second word line dielectric layer 301. Remaining first insulating material 713 within the first trench TR1 may be referred to as a first thickening layer 431, and remaining first insulating material 713 within the second trench TR2 may be referred to as a second thickening layer 441. Additionally, remaining capping material 751 within the first trench TR1 may be referred to as the first capping layer 207 and remaining capping material 751 within the second trench TR2 may be referred to as the second capping layer 307.

The first word line dielectric layer 201, the first bottom conductive layer 203, the first top conductive layer 205, and the first capping layer 207 together comprise a first word line structure 200. The second word line dielectric layer 301, the second bottom conductive layer 303, the second top conductive layer 305, and the second capping layer 307 together comprise the second word line structure 300. In some embodiments, a bottom surface 200BS of the first word line structure 200 may be higher than a bottom surface 300BS of the second word line structure 300.

With reference to FIG. 16, the first capping layer 207 may have a T-shaped cross-sectional profile, conforming to contours of the first extended inner trench 533. The first capping layer 207 may include a bottom portion 207-1 and a top portion 207-3. The bottom portion 207-1 may penetrate through the first top conductive layer 205 and the first middle barrier layer 413 and extend down to the first bottom conductive layer 203. Positioned above the bottom portion 207-1, the top portion 207-3 may rest on both the bottom portion 207-1 and the first top conductive layer 205 and may be laterally surrounded by the first thickening layer 431. In some embodiments, a width W1 of the top portion 207-3 may be greater than a width W2 of the bottom portion 207-1. Similarly, the second capping layer 307 may feature a similar structure, with a bottom portion 307-1 and a top portion 307-3 analogous to the bottom portion 207-1 and the top portion 207-3 of the first capping layer 207, and further details of the components are not repeated. In some embodiments, a ratio of the width W1 of the top portion 207-3 to the width W2 of the bottom portion 207-1 may be between about 4.0 and about 1.5.

In some embodiments, the first bottom conductive layer 203 and the first top conductive layer 205 may be composed of materials with differing work functions, effectively reducing a gate-induced drain leakage in the first word line structure 200. Additionally, replacing sections of the first top conductive layer 205 with the bottom portion 207-1 of the first capping layer 207 may help mitigate issues such as line end wiggling. Moreover, incorporating the first thickening layer 431 may enhance an insulating capability of the first word line dielectric layer 201 by increasing a thickness of the first word line dielectric layer 201. Therefore, preventing the word line dielectric layer 201 from being consumed during processes such as etch-back or cleaning can help mitigate gate-induced drain leakage.

FIG. 17 illustrates, in a schematic cross-sectional view diagram, a semiconductor device 1B in accordance with another embodiment of the present disclosure.

With reference to FIG. 17, the semiconductor device 1B may have a structure similar to that of the semiconductor device 1A illustrated in FIG. 16. Elements in FIG. 17 that are same as or similar to elements in FIG. 16 are marked with similar reference numbers and duplicative descriptions are omitted.

During formation of the semiconductor device 1B, the planarization process as illustrated in FIG. 16 may be performed until the bottom dielectric layer 107 is exposed so that the bottom dielectric layer 107 may be kept intact or only partially removed. Therefore, the first word line dielectric layer 201 (or the second word line dielectric layer 301) may be laterally surrounded by the bottom dielectric layer 107. The top portion 207-3 (or the top portion 307-3) may be thicker along the direction Z than the top portion 207-3 (or the top portion 307-3) in FIG. 16. The bottom dielectric layer 107 may serve as a buffer layer, a protection layer, or an etch stop layer for subsequent processes.

FIGS. 18 and 19 illustrate, in schematic cross-sectional view diagrams, part of a process for fabricating a semiconductor device 1C in accordance with another embodiment of the present disclosure.

With reference to FIG. 18, an intermediate semiconductor device may be fabricated with a procedure similar to that illustrated in FIG. 13. The layer of capping material 751 may be formed to fill the first trench TR1 and the second trench TR2 with a procedure similar to that illustrated in FIG. 15, and descriptions thereof are not repeated. It should be noted that the plurality of first spacers 511 and the plurality of second spacers 521 are not removed before the depositing of the capping material 751.

With reference to FIG. 19, a planarization process similar to that illustrated in FIG. 16 may be performed, and descriptions thereof are not repeated. During the formation of the semiconductor device 1C, the first capping layer 207 may have a line-shaped cross-sectional profile. The upper portion of the first capping layer 207 may be laterally surrounded by the plurality of first spacers 511. In some embodiments, top surfaces 511TS of the plurality of first spacers 511, a top surface 207TS of the first capping layer 207, a top surface 431TS of the first thickening layer 431, and a top surface 201TS of the first word line dielectric layer 201 may be substantially coplanar. Similarly, the second capping layer 307 may feature a structure similar to the structure of the first capping layer 207, and further details are not repeated. In some embodiments, a ratio of a width W3 of the first capping layer 207 to a width W4 of the first bottom conductive layer 203 may be between about 0.20 and about 0.80.

FIG. 20 illustrates, in a schematic cross-sectional view diagram, a semiconductor device 1D in accordance with another embodiment of the present disclosure.

With reference to FIG. 20, the semiconductor device 1D may have a structure similar to that of the semiconductor device 1C illustrated in FIG. 19. Elements in FIG. 20 that are same as or similar to elements in FIG. 19 are marked with similar reference numbers and duplicative descriptions are omitted.

During formation of the semiconductor device 1D, the planarization process illustrated in FIG. 16 may be performed until the bottom dielectric layer 107 is exposed so that the bottom dielectric layer 107 may be kept intact or only partially removed. Therefore, the first word line dielectric layer 201 (or the second word line dielectric layer 301) may be laterally surrounded by the bottom dielectric layer 107. The first capping layer 207 (or the second capping layer 307) may be thicker along the direction Z than the top portion 207-3 (or the top portion 307-3) illustrated in FIG. 19. The bottom dielectric layer 107 may serve as a buffer layer, a protection layer, or an etch stop layer for subsequent processes.

FIGS. 21 to 23 illustrate, in schematic cross-sectional view diagrams, part of a process for fabricating a semiconductor device in accordance with another embodiment of the present disclosure.

With reference to FIG. 21, an intermediate semiconductor device may be fabricated with a procedure similar to the procedure illustrated in FIGS. 2 to 16. An opening 170 is formed penetrating through a dielectric layer 113 and extending into the drain region 105-3. The opening 170 may be formed by an etching process, and a location of the opening 170 may be defined by a patterned mask formed over the dielectric layer 113. The etching process may include a dry etching process, a wet etching process, or a combination thereof. After the etching process is performed, the patterned mask may be removed.

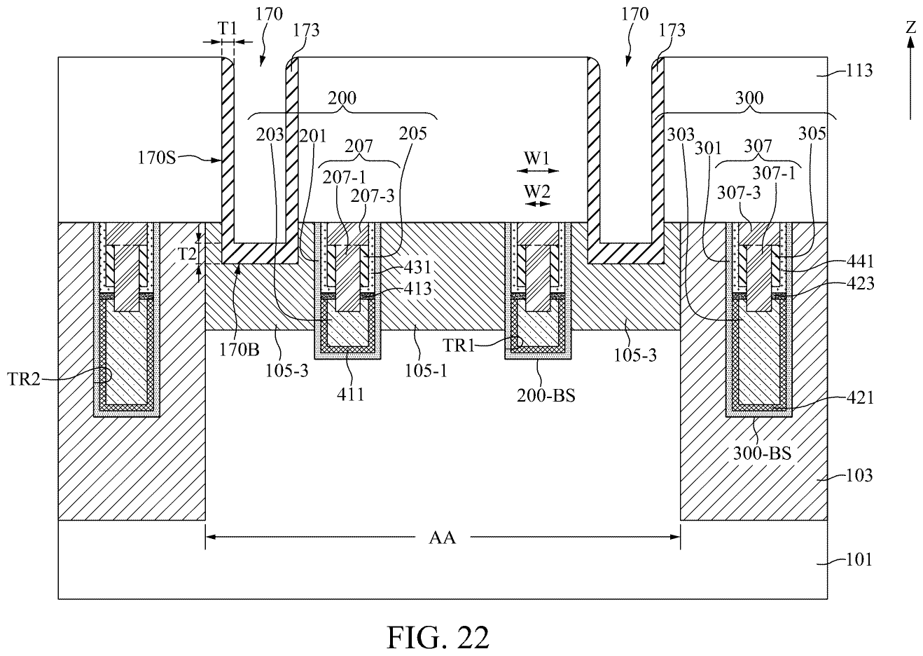

With reference to FIG. 22, an anisotropic deposition process is performed to form a barrier layer 173 covering a sidewall 170S and a bottom surface 170B of the opening 170. In some embodiments, the barrier layer 173 includes titanium (Ti), titanium nitride (TiN), or a combination thereof. In some embodiments, the anisotropic deposition process is performed so as to ensure that a first thicknesses T1 of the barrier layer 173 on the sidewall 170S of the opening 170 is less than a second thickness T2 of the barrier layer 173 on the bottom surface 170B of the opening 170. In some embodiments, the anisotropic deposition process includes a physical vapor deposition (PVD) process.

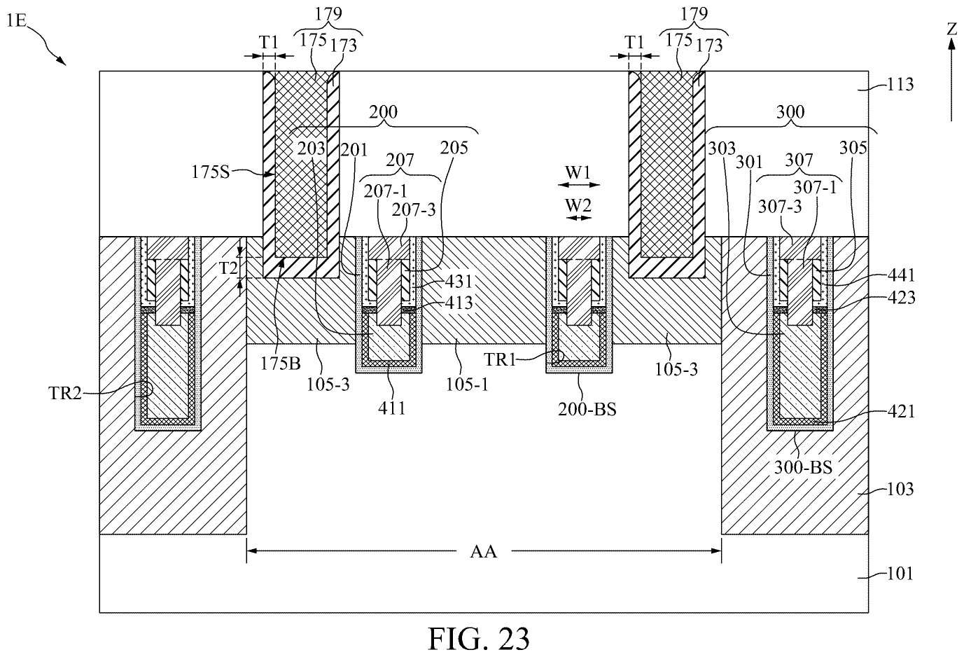

With reference to FIG. 23, subsequently, a conductive layer 175 is formed in the remaining portion of the opening 170 over the barrier layer 173, thereby forming a conductive contact 179 including the barrier layer 173 and the conductive layer 175. In some embodiments, the conductive layer 175 includes tungsten (W). Moreover, the conductive layer 175 may be formed using a deposition process and a subsequent planarization process. After the formation of the conductive contact 179, a semiconductor device 1E is obtained.

FIGS. 24 to 32 illustrate, in schematic cross-sectional view diagrams, part of a process for fabricating a semiconductor device in accordance with another embodiment of the present disclosure.

With reference to FIG. 24, an intermediate semiconductor device may be fabricated with a procedure similar to the procedure illustrated in FIGS. 21 to 23. A first conductive layer 108 and a second conductive layer 120 are sequentially formed on the current structure. In other words, the conductive contact 179 and the first dielectric layer 113 may be covered by the first and second conductive layers 108, 120. The second conductive layer 120 is stacked on the first conductive layer 108. A conductive pillar 116 and a landing pad CP are to be formed by patterning the first and second conductive layers 108, 120 in the following steps. In some embodiments, the first conductive layer 108 has a thickness greater than a thickness of the second conductive layer 120. In addition, in some embodiments, a conductive material of the second conductive layer 120 has a resistivity less than a resistivity of a conductive material of the first conductive layer 108, and the conductive material of the first conductive layer 108 has a sufficient etching selectivity with respect to the conductive material of the second conductive layer 120. A method for the formation of the conductive layers 118 and 120 may include a deposition process (e.g., a PVD process), a plating process or a combination thereof.

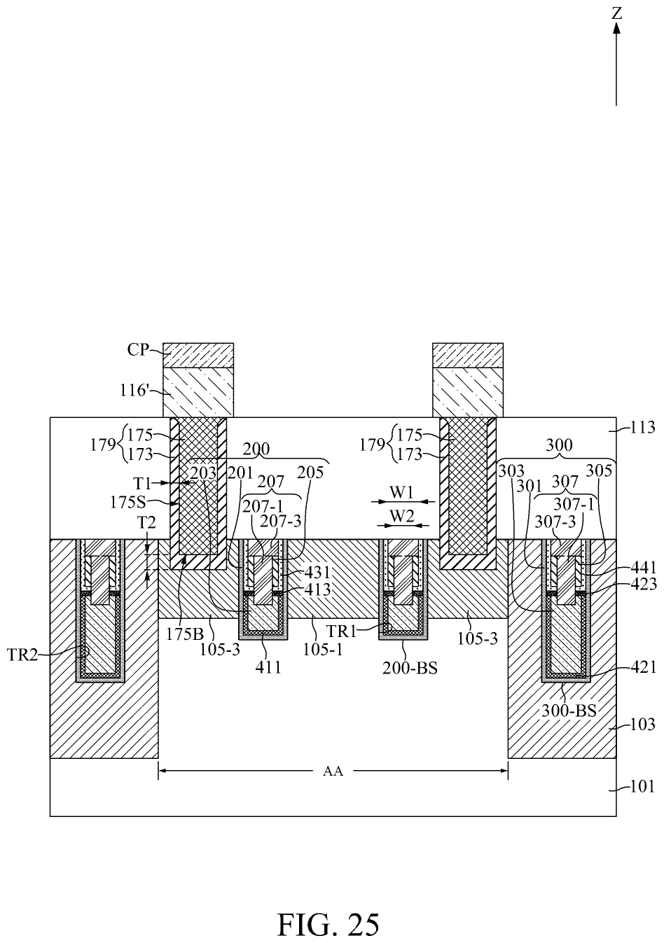

With reference to FIG. 25, the first and second conductive layers 108, 120 are patterned to form an initial conductive pillar 116′ and the landing pad CP. During the patterning process, portions of the first and second conductive layers 108, 120 are removed, and the first dielectric layer 113 may be exposed. A sidewall of the formed initial conductive pillar 116′ may be substantially coplanar with a sidewall of the formed landing pad CP. In other words, a footprint area of each initial conductive pillar 116′ may be substantially identical to a footprint area of the overlying landing pad CP. The conductive pillar 116 will be formed by laterally recessing the initial conductive pillar 116′ in the following step. In some embodiments, a method of the formation of the initial conductive pillar 116′ and the landing pad CP may include a lithography process and a single etching process (e.g., a single anisotropic etching process). In some embodiments, the first and second conductive layers 108, 120 are partially removed in a same etching process. In alternative embodiments, a method for the formation of the initial conductive pillars 116′ and the landing pads CP uses two etching processes (e.g., two anisotropic etching processes). In such embodiments, a first etching process is performed for the formation of the landing pads CP, and a second etching process is performed for the formation of the initial conductive pillars 116′.

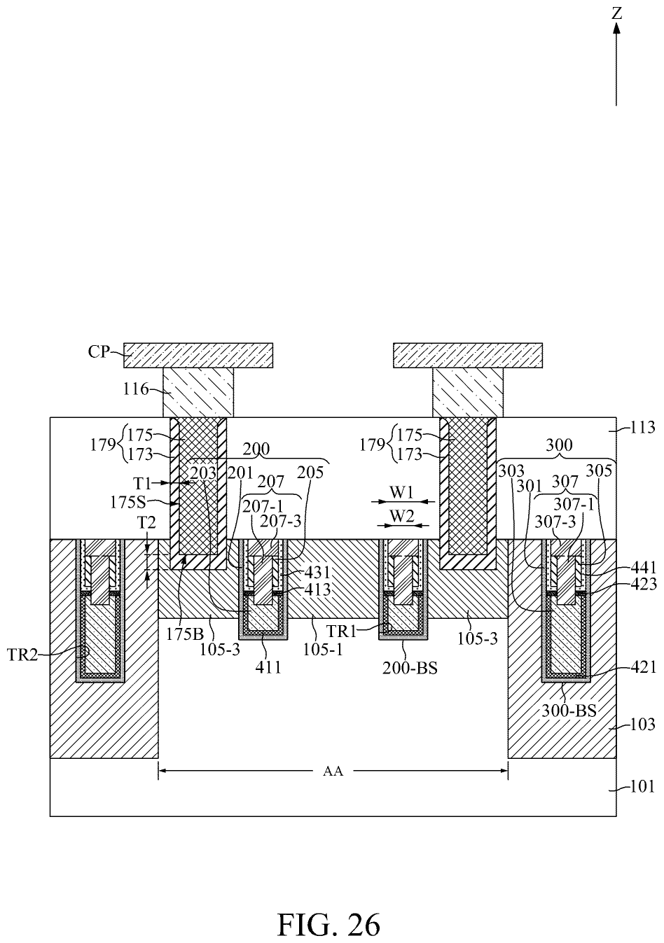

With reference to FIG. 26, the initial conductive pillar 116′ is laterally recessed, so as to form the conductive pillar 116. In some embodiments, a method for the lateral recessing of the initial conductive pillar 116′ includes an isotropic etching process (e.g., a wet etching process). In embodiments where conductive materials used for forming the landing pads CP exhibit sufficient etching selectivity relative to the conductive materials used for the initial conductive pillars 116′, the landing pads CP may avoid being damaged (or may be only slightly consumed) during such isotropic etching process. As a consequence, the formed conductive pillar 116 can be laterally recessed with respect to the landing pads CP. The landing pad CP and the conductive pillar 116 are respectively made of different conductive materials. As mentioned above, a resistivity of the conductive material of the landing pads CP is less than a resistivity of the conductive material of the conductive pillars 116, and the conductive material of the conductive pillars 116 has a sufficient etching selectivity with respect to the conductive material of the landing pads CP.

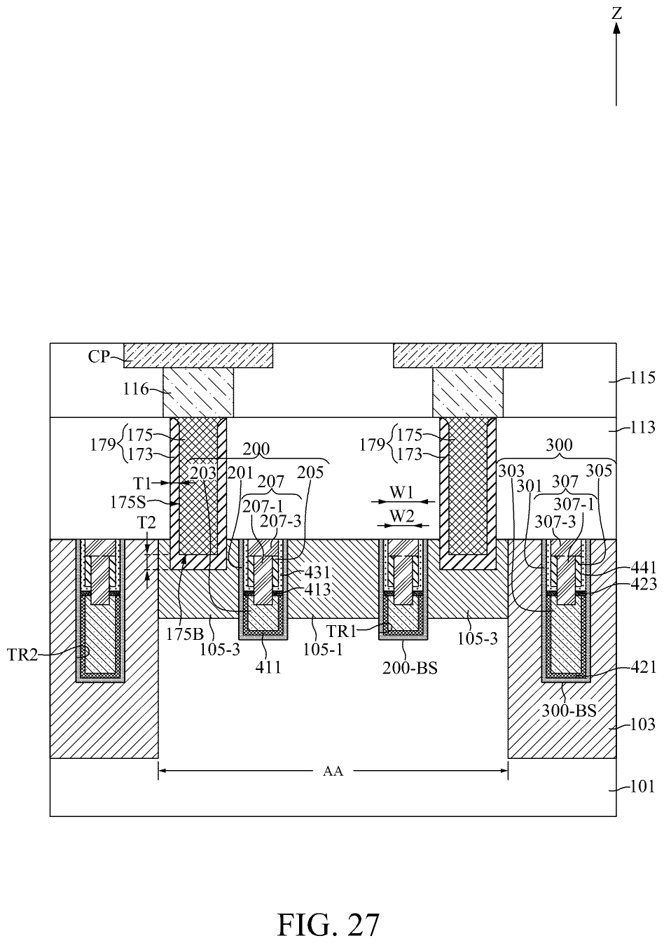

With reference to FIG. 27, a second dielectric layer 115 is formed surrounding the conductive pillar 116 and the landing pad CP. A top surface of the second dielectric layer 115 is substantially coplanar with a top surface of the landing pad CP. A material of the second dielectric layer 115 may be same as a material of the first dielectric layer 113. In some embodiments, a method for formation of the second dielectric layer 115 includes a deposition process (e.g., a CVD process) and may further include a planarization process for removing excess material above the landing pads CP.

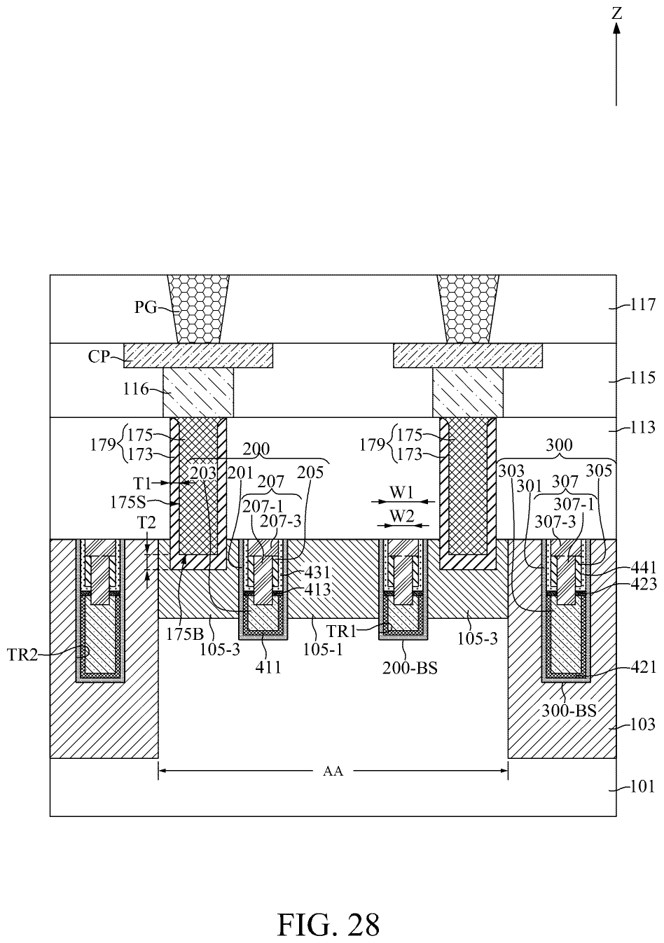

With reference to FIG. 28, capacitor plugs PG and a third dielectric layer 117 are formed on the second dielectric layer 115. The third dielectric layer 117 is located on the second dielectric layer 115 and the landing pad CP. The capacitor plug PG is disposed in the third dielectric layer 117 and penetrates through the third dielectric layer 117, establishing an electrical connection with the landing pad CP. In some embodiments, the third dielectric layer 117 may be globally formed on the second dielectric layer 115 and the landing pad CP using a deposition process (e.g., a CVD process). Next, a through hole is formed in third dielectric layer 117 using a lithography process and an etching process (e.g., an anisotropic etching process). Subsequently, a conductive material is deposited in the through hole using a deposition process (e.g., a PVD process), a plating process or a combination thereof, and a planarization process may be performed to remove portions of the conductive material over the third dielectric layer 117. As a result, remaining portions of the conductive material form the capacitor plugs PG.

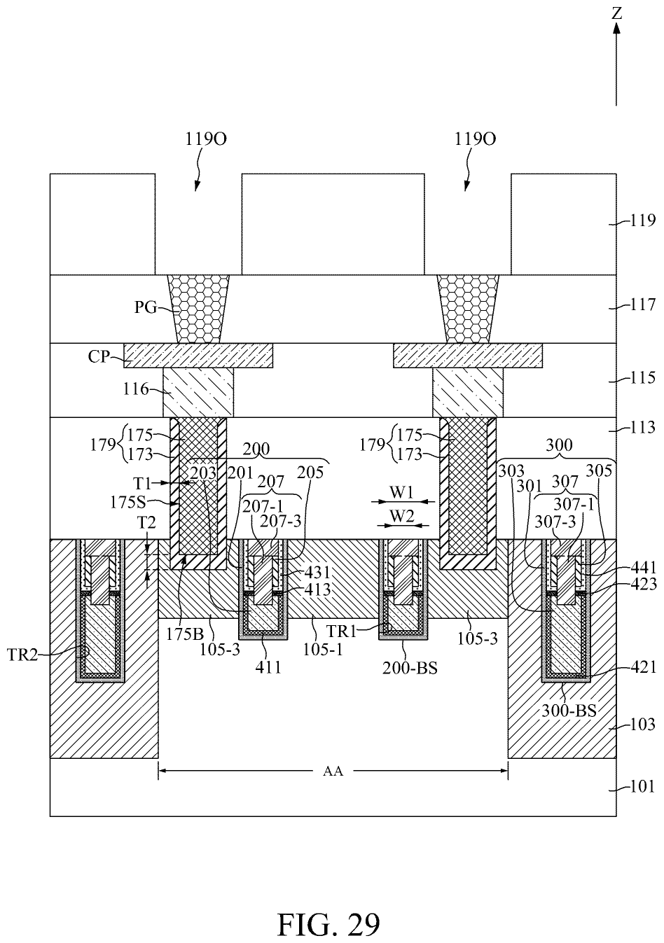

With reference to FIG. 29, a fourth dielectric layer 119 is formed on the third dielectric layer 117 and the capacitor plugs PG. The fourth dielectric layer 119 is located on the third dielectric layer 117, and has an opening 1190 overlapping the capacitor plugs PG. In some embodiments, the opening 1190 further overlaps portions of the third dielectric layer 117 surrounding the capacitor plug PG. In some embodiments, the fourth dielectric layer 119 may be globally formed on the third dielectric layer 117 and on the capacitor plugs PG using a deposition process, such as a chemical vapor deposition (CVD) process. In some embodiments, the opening 1190 is formed in the fourth dielectric layer 119 using a lithography process and an etching process, such as an anisotropic etching process.

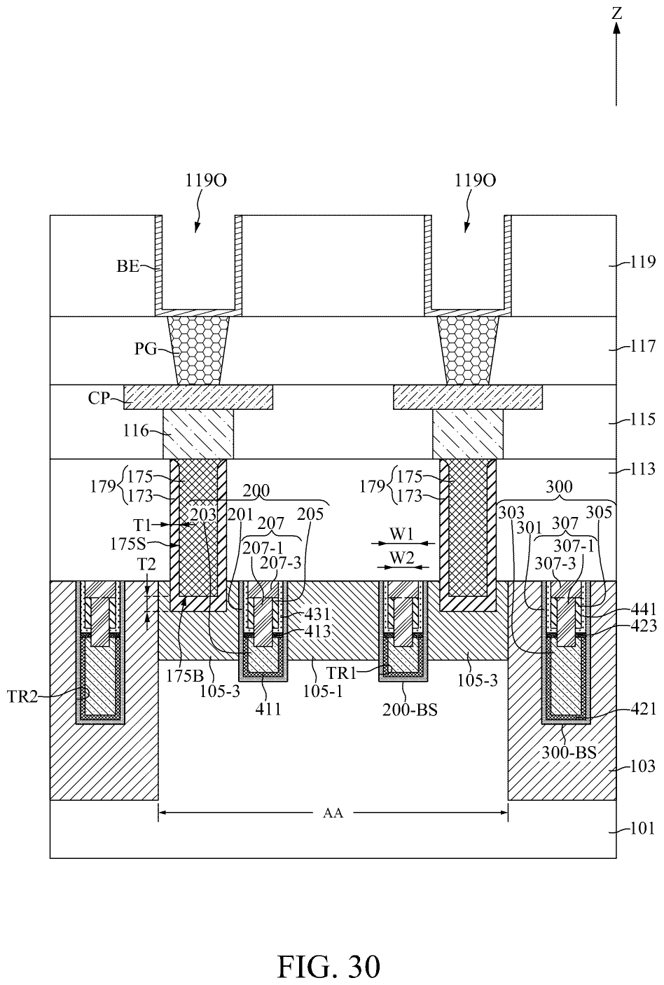

With reference to FIG. 30, a bottom electrode BE is formed on the exposed capacitor plugs PG. The bottom electrode BE is conformally formed in the opening 1190 of the fourth dielectric layer 119. Accordingly, the bottom electrode BE may cover the capacitor plug PG, and may establish an electrical connection with the capacitor plug PG. In embodiments where the opening 1190 of the fourth dielectric layer 119 further overlaps portions of the third dielectric layer 117 surrounding the capacitor plugs PG, the portions of the third dielectric layer 117 are covered by the bottom electrodes BE. In some embodiments, a conductive material layer is conformally formed to cover the fourth dielectric layer 119 and the exposed surface of the capacitor plugs PG and the third dielectric layer 117. Thereafter, a planarization process is performed to remove portions of the conductive material layer over the fourth dielectric layer 119. Remaining portions of the conductive material layer form the bottom electrodes BE.

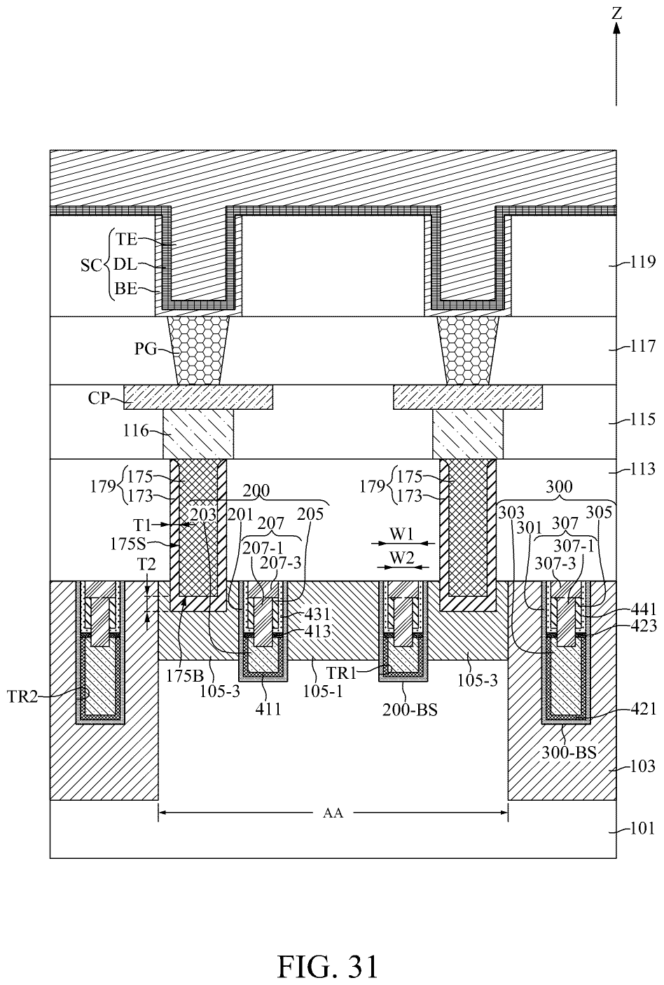

With reference to FIG. 31, a dielectric layer DL and a top electrode TE are sequentially formed on the fourth dielectric layer 119 and the bottom electrodes BE. The dielectric layer DL conformally covers exposed surfaces of the fourth dielectric layer 119 and the bottom electrodes BE. The top electrode TE fills the opening 1190 of the fourth dielectric layer 119, and covers a top surface of the dielectric layer DL. In some embodiments, the dielectric layer DL and the top electrode TE are globally formed. A method for forming the dielectric layer DL may include a deposition process (e.g., a CVD process), and a method for forming the top electrode TE may include a deposition process (e.g., a PVD process), a plating process or a combination thereof.

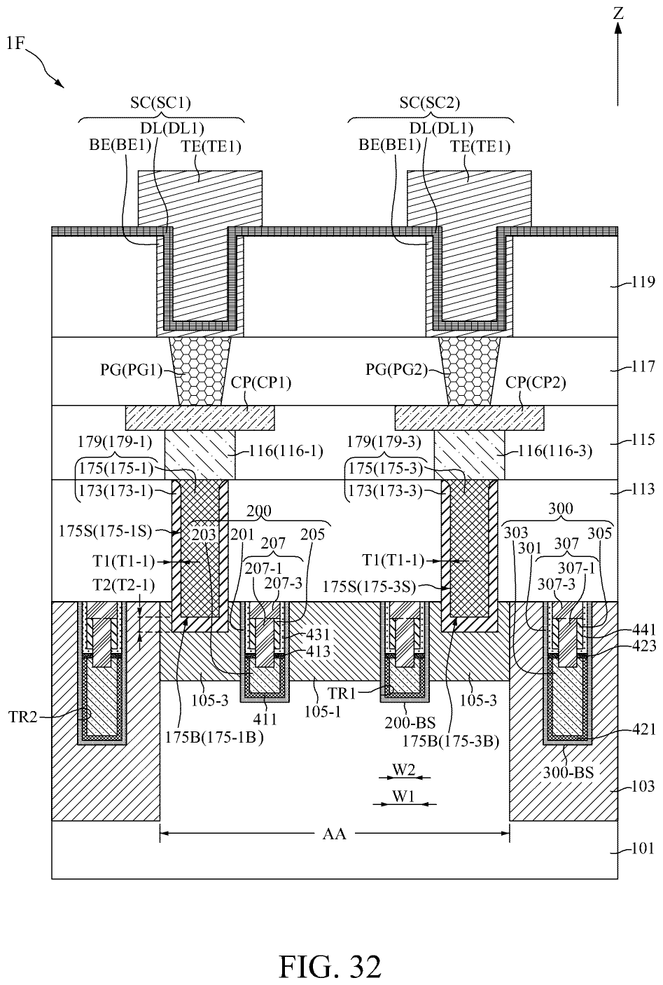

With reference to FIG. 32, in some embodiments, a trimming process, such as an isotropic etching process, an anisotropic process, or a combination thereof, is performed to remove portions of the dielectric layer DL and the top electrode TE. After the trimming of the dielectric layer DL and the top electrode is performed, a semiconductor device 1F having a T-shape profile storage capacitor SC is obtained.

One aspect of the present disclosure provides a semiconductor device including a substrate with a source region and a drain region; a first word line structure disposed between the source region and the drain region; a first dielectric layer positioned over the substrate; and a conductive contact penetrating through the first dielectric layer and extending into the drain region of the substrate. The first word line structure includes a first word line dielectric layer positioned in the substrate and including a U-shaped cross-sectional profile, a first bottom conductive layer positioned on the first word line dielectric layer and laterally surrounded by the first word line dielectric layer, a first top conductive layer positioned on the first bottom conductive layer and laterally surrounded by the first word line dielectric layer, a first capping layer including a bottom portion penetrating through the first top conductive layer and extending to the first bottom conductive layer, and a top portion positioned on the bottom portion and laterally surrounded by the first word line dielectric layer. The conductive contact comprises a conductive layer and a barrier layer covering a sidewall and a bottom surface of the conductive layer. A first thickness of the barrier layer on the sidewall of the conductive layer is less than a second thickness of the barrier layer under the bottom surface of the conductive layer.

Another aspect of the present disclosure provides a semiconductor device including a substrate with a source region and a plurality of drain regions; a plurality of isolation layers disposed in the substrate; a first word line structure disposed in the substrate and between the isolation layers; a second word line structure disposed in the isolation layers; a first dielectric layer disposed over the substrate; a second dielectric layer disposed over the first dielectric layer; a first conductive contact and a second conductive contact respectively penetrating through the first dielectric layer and extending into one of the drain regions; a first conductive pillar and a second conductive pillar disposed on the first conductive contact and the second conductive contact, respectively; and a first landing pad and a second landing pad disposed on the first conductive pillar and the second conductive pillar, respectively. The first and second landing pads and the first and second conductive pillars are respectively made of different conductive materials, and a resistivity of the first and second landing pads is less than a resistivity of the first and second conductive pillars.

Another aspect of the present disclosure provides a method for fabricating a semiconductor device including providing a substrate, forming a first trench in the substrate, and conformally forming a layer of first dielectric material in the first trench; forming a first bottom conductive layer on the layer of first dielectric material within the first trench, and forming a first top conductive layer on the first bottom conductive layer within the first trench; conformally forming a layer of spacer material on the first top conductive layer and the layer of first dielectric material; performing a punch-through process to turn the layer of spacer material into a plurality of first spacers attached to the layer of first dielectric material, resulting in a first inner trench, which separates the plurality of first spacers and partially exposes the first top conductive layer; deepening the first inner trench to form a first extended inner trench that penetrates the first top conductive layer and extends to the first bottom conductive layer; removing the plurality of first spacers and forming a layer of capping material to completely fill the first trench; performing a planarization process to turn the layer of first dielectric material into a first word line dielectric layer and turn the layer of capping material into a first capping layer; depositing a first dielectric layer on the substrate; perform an etching process to form an opening penetrating through the first dielectric layer and extending into the substrate; performing an anisotropic deposition process to form a barrier layer covering a sidewall and a bottom surface of the opening; and forming a conductive layer disposed over and surrounded by the barrier layer. The first word line dielectric layer, the first bottom conductive layer, the first top conductive layer, and the first capping layer together comprise a first word line structure. A first thickness of the barrier layer on the sidewall of the opening is less than a second thickness of the barrier layer on the bottom surface of the opening.

Another aspect of the present disclosure provides a method for fabricating a semiconductor device including providing a semiconductor structure, wherein the semiconductor structure comprises a substrate with a source region and a plurality of drain regions, a plurality of first word line structures disposed in the substrate, a first dielectric layer disposed over the substrate and the first word line structures, and a plurality of conductive contacts penetrating through the first dielectric layer and extending into the drain regions; forming a first conductive layer on the first dielectric layer and the conductive contacts, and forming a second conductive layer on the first conductive layer; performing a first etching process on the second conductive layer to form a first landing pad over one of the conductive contacts and a second landing pad over another one of the conductive contacts; and performing a second etching process on the first conductive layer to form a first conductive pillar below the first landing pad and a second conductive pillar below the second landing pad. The first word line structure comprises a first word line dielectric layer positioned in the substrate and comprising a U-shaped cross-sectional profile; a first bottom conductive layer positioned on the first word line dielectric layer and laterally surrounded by the first word line dielectric layer; a first top conductive layer positioned on the first bottom conductive layer and laterally surrounded by the first word line dielectric layer; and a first capping layer comprising a bottom portion penetrating through the first top conductive layer and extending to the first bottom conductive layer; and a top portion positioned on the bottom portion and laterally surrounded by the first word line dielectric layer. The first and second landing pads and the first and second conductive pillars are respectively made of different conductive materials, and a resistivity of the first and second landing pads is less than a resistivity of the first and second conductive pillars.

Due to a design of a semiconductor device of the present disclosure, issues such as line end wiggling may be mitigated by substituting sections of a first top conductive layer with a bottom portion of a first capping layer. Furthermore, a gate-induced drain leakage is minimized by using a first bottom conductive layer and the first top conductive layer composed of materials with differing work functions. In addition, integration of a first thickening layer increases an insulating capability of a first word line dielectric layer by augmenting a thickness of the first word line dielectric layer. Such enhancement is particularly advantageous, as the word line dielectric layer may be susceptible to depletion during processes like an etch-back process or a cleaning process, which could otherwise exacerbate a gate-induced drain leakage.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate with a source region and a plurality of drain regions;
a plurality of isolation layers disposed in the substrate;
a first word line structure disposed in the substrate and between the isolation layers;
a second word line structure disposed in the isolation layers;
a first dielectric layer disposed over the substrate;
a second dielectric layer disposed over the first dielectric layer;
a first conductive contact and a second conductive contact respectively disposed penetrating through the first dielectric layer and extending into one of the drain regions;
a first conductive pillar and a second conductive pillar disposed on the first conductive contact and the second conductive contact, respectively; and
a first landing pad and a second landing pad disposed on the first conductive pillar and the second conductive pillar, respectively,
wherein the first and second landing pads and the first and second conductive pillars are respectively made of different conductive materials, and a resistivity of the first and second landing pads is lower than a resistivity of the first and second conductive pillars.

2. The semiconductor device of claim 1, wherein the first word line structure comprises:
a first word line dielectric layer positioned in the substrate and comprising a U-shaped cross-sectional profile;
a first bottom conductive layer positioned on the first word line dielectric layer and laterally surrounded by the first word line dielectric layer;
a first top conductive layer positioned on the first bottom conductive layer and laterally surrounded by the first word line dielectric layer; and
a first capping layer comprising:
a bottom portion positioned penetrating through the first top conductive layer and extending to the first bottom conductive layer; and
a top portion positioned on the bottom portion and laterally surrounded by the first word line dielectric layer.

3. The semiconductor device of claim 1, wherein the second word line structure comprises:
a second word line dielectric layer positioned in the substrate and comprising a U-shaped cross-sectional profile;
a second bottom conductive layer positioned on the second word line dielectric layer and laterally surrounded by the second word line dielectric layer;
a second top conductive layer positioned on the second bottom conductive layer and laterally surrounded by the second word line dielectric layer; and
a second capping layer comprising:
a bottom portion positioned penetrating through the second top conductive layer and extending to the second bottom conductive layer; and
a top portion positioned on the bottom portion and laterally surrounded by the second word line dielectric layer.

4. The semiconductor device of claim 1, wherein the first conductive contact comprises a first conductive layer and a first barrier layer covering a first sidewall and a first bottom surface of the first conductive layer, and wherein a side thickness of the first barrier layer on the first sidewall of the first conductive layer is less than a bottom thickness of the first barrier layer under the first bottom surface of the first conductive layer.

5. The semiconductor device of claim 1, wherein the second conductive contact comprises a second conductive layer and a second barrier layer covering a second sidewall and a second bottom surface of the second conductive layer, and wherein a side thickness of the second barrier layer on the second sidewall of the second conductive layer is less than a bottom thickness of the second barrier layer under the second bottom surface of the second conductive layer.

6. The semiconductor device of claim 1, further comprising:
a third dielectric layer disposed over the second dielectric layer; and
a fourth dielectric layer disposed over the third dielectric layer.

7. The semiconductor device of claim 6, further comprising:
a first capacitor plug and a second capacitor plug disposed in the third dielectric layer, wherein the first capacitor plug is disposed on the first landing pad and the second capacitor plug is disposed on the second landing pad; and
a first storage capacitor and a second storage capacitor both disposed in the fourth dielectric layer, wherein the first storage capacitor is disposed on the first capacitor plug and the second storage capacitor is disposed on the second capacitor plug.

8. A method for fabricating a semiconductor device, comprising:
providing a substrate and forming a first trench in the substrate, and conformally forming a layer of first dielectric material in the first trench;
forming a first bottom conductive layer on the layer of first dielectric material and within the first trench, and forming a first top conductive layer on the first bottom conductive layer and within the first trench;
conformally forming a layer of spacer material on the first top conductive layer and the layer of first dielectric material;
performing a punch-through process to turn the layer of spacer material into a plurality of first spacers attached to the layer of first dielectric material, resulting in a first inner trench, which separates the plurality of first spacers and partially exposes the first top conductive layer;
deepening the first inner trench to form a first extended inner trench that penetrates the first top conductive layer and extends to the first bottom conductive layer;
removing the plurality of first spacers and forming a layer of capping material to completely fill the first trench;
performing a planarization process to turn the layer of first dielectric material into a first word line dielectric layer and turn the layer of capping material into a first capping layer;
depositing a first dielectric layer on the substrate;
performing an etching process to form an opening penetrating through the first dielectric layer and extending into the substrate;
performing an anisotropic deposition process to form a barrier layer covering a sidewall and a bottom surface of the opening; and
forming a conductive layer disposed over and surrounded by the barrier layer,
wherein the first word line dielectric layer, the first bottom conductive layer, the first top conductive layer, and the first capping layer together configure a first word line structure,
wherein a first thickness of the barrier layer on the sidewall of the conductive layer is less than a second thickness of the barrier layer under the bottom surface of the conductive layer.

9. The method of claim 8, wherein the first capping layer comprises a bottom portion and a top portion, the bottom portion penetrates through the first top conductive layer and extends to the first bottom conductive layer, and the first bottom conductive layer is formed on the bottom portion and the first top conductive layer.

10. The method of claim 9, wherein a width ratio of a width of the top portion to a width of the bottom portion is between about 4.0 and about 1.5.

11. The method of claim 9, wherein the first bottom conductive layer comprises tungsten, cobalt, zirconium, tantalum, aluminum, ruthenium, copper, metal carbides, transition metal aluminides, or a combination thereof.

12. The method of claim 9, wherein the first top conductive layer comprises polycrystalline silicon, polycrystalline germanium, polycrystalline silicon germanium, doped polycrystalline silicon, doped polycrystalline germanium, doped polycrystalline silicon germanium, or a combination thereof.

13. The method of claim 8, wherein barrier layer comprises titanium (Ti), titanium nitride (TiN), or a combination thereof.

14. The method of claim 8, wherein conductive layer comprises tungsten (W).

15. A method for fabricating a semiconductor device, comprising:
providing a semiconductor structure, wherein the semiconductor structure comprises:
a substrate with a source region and a plurality of drain regions;
a plurality of first word line structures disposed in the substrate;
a first dielectric layer disposed over the substrate and the first word line structures; and
a plurality of conductive contacts positioned penetrating through the first dielectric layer and extending into the drain regions,
wherein the first word line structure comprises a first word line dielectric layer positioned in the substrate and comprising a U-shaped cross-sectional profile; a first bottom conductive layer positioned on the first word line dielectric layer and laterally surrounded by the first word line dielectric layer; a first top conductive layer positioned on the first bottom conductive layer and laterally surrounded by the first word line dielectric layer; and a first capping layer comprising a bottom portion positioned penetrating through the first top conductive layer and extending to the first bottom conductive layer; and a top portion positioned on the bottom portion and laterally surrounded by the first word line dielectric layer;
forming a first conductive layer on the first dielectric layer and the conductive contacts, and forming a second conductive layer on the first conductive layer;
performing a first etching process on the second conductive layer to form a first landing pad over one of the conductive contacts, and a second landing pad over another conductive contact; and
performing a second etching process on the first conductive layer to form a first conductive pillar below the first landing pad, and a second conductive pillar below the second landing pad,
wherein the first and second landing pads and the first and second conductive pillars are respectively made of different conductive materials, and a resistivity of the first and second landing pads is lower than a resistivity of the first and second conductive pillars.

16. The semiconductor device of claim 15, further comprising:
forming a second dielectric layer on the first dielectric layer and surrounding the first landing pad, the second landing pad, the first conductive pillar, and the second conductive pillar;
forming a third dielectric layer over the second dielectric layer; forming a first capacitor plug in the third dielectric layer and on first landing pad; and
forming a second capacitor plug in the third dielectric layer and on second landing pad.

17. The semiconductor device of claim 16, further comprising:
forming a fourth dielectric layer over the third dielectric layer; and
forming a first storage capacitor in the fourth dielectric layer and on the first capacitor plug; and
forming second storage capacitor in the fourth and on the second capacitor plug.
